(19) United States
(12) Patent Application Publication
(10) Pub. No.: US 2025/0060683 A1
(43) Pub. Date: Feb. 20, 2025

(54) PHOTOSENSITIVE SUBSTRATE DEVELOPING METHOD, PHOTOMASK CREATING METHOD, AND ELECTRONIC DEVICE MANUFACTURING METHOD

(71) Applicant: Gigaphoton Inc., Tochigi (JP)

(72) Inventor: Koichi FUJII, Oyama-shi (JP)

(73) Assignee: Gigaphoton Inc., Tochigi (JP)

(21) Appl. No.: 18/940,386

(22) Filed: Nov. 7, 2024

Related U.S. Application Data
(63) Continuation of application No. PCT/JP2022/022503, filed on Jun. 2, 2022.

(51) Int. Cl. G03F 7/00; G03F 7/32

(52) U.S. Cl. CPC G03F 7/70875; G03F 7/32; G03F 7/70041; G03F 7/70358; G03F 7/70575

(57) ABSTRACT

A photosensitive substrate developing method includes heating a photosensitive substrate exposed by scanning each of a plurality of scan fields included in the photosensitive substrate in a first direction with a pulse laser beam including a plurality of center wavelengths via a photomask so as to have a temperature distribution having a temperature gradient in a second direction intersecting the first direction on a surface of the photosensitive substrate in each of the scan fields, and supplying a developer to the surface of the photosensitive substrate to perform development after heating the photosensitive substrate.

### CROSS-REFERENCE TO RELATED APPLICATIONS

The present application is a continuation application of International Application No. PCT/JP2022/022503, filed on Jun. 2, 2022, the entire contents of which are hereby incorporated by reference.

### BACKGROUND

### 1. Technical Field

The present disclosure relates to a photosensitive substrate developing method, a photomask creating method, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser apparatus for exposure, a KrF excimer laser apparatus that outputs a laser beam having a wavelength of about 248 nm and an ArF excimer laser apparatus that outputs a laser beam having a wavelength of about 193 nm are used.

Spectral linewidths of spontaneous oscillation beams of the KrF excimer laser apparatus and the ArF excimer laser apparatus are as wide as from 350 pm to 400 pm. Therefore, when a projection lens is formed of a material that transmits ultraviolet light such as KrF and ArF laser beams, chromatic aberration may occur. As a result, the resolution may decrease. Thus, the spectral linewidth of the laser beam output from the gas laser apparatus needs to be narrowed to an extent that the chromatic aberration is ignorable. Therefore, in a laser resonator of the gas laser apparatus, a line narrowing module (LNM) including a line narrowing element (such as etalon or grating) may be provided in order to narrow the spectral linewidth. A gas laser apparatus with a narrowed spectral linewidth is referred to as a line narrowing gas laser apparatus.

### LIST OF DOCUMENTS

### Patent Document

Patent Document 1: U.S. Pat. No. 5,968,691

### SUMMARY

In one aspect of the present disclosure, a photosensitive substrate developing method includes heating a photosensitive substrate exposed by scanning each of a plurality of scan fields included in the photosensitive substrate in a first direction with a pulse laser beam including a plurality of center wavelengths via a photomask so as to have a temperature distribution having a temperature gradient in a second direction intersecting the first direction on a surface of the photosensitive substrate in each of the scan fields, and supplying a developer to the surface of the photosensitive substrate to perform development after heating the photosensitive substrate.

In one aspect of the present disclosure, a creating method of a photomask used in photolithography using a pulse laser beam including a plurality of center wavelengths includes measuring a wafer pattern of a second test wafer that is exposed by scanning the second test wafer in a first direction with a pulse laser beam via a second test mask and is developed by supplying a developer to a surface of the second test wafer heated so as to have a temperature distribution having a temperature gradient in a second direction intersecting the first direction on the surface of the second test wafer in each of a plurality of scan fields included in the second test wafer, to acquire a measured wafer pattern indicating measurement results in each of a plurality of divided regions aligned in the second direction, creating a corrected mask pattern for creating the photomask based on a test mask pattern formed on the second test mask, the measured wafer pattern, and a target pattern which is a target wafer pattern of a photosensitive substrate, and creating the photomask based on the corrected mask pattern.

In one aspect of the present disclosure, an electronic device manufacturing method includes generating a pulse laser beam including a plurality of center wavelengths with a laser apparatus, outputting the pulse laser beam to an exposure apparatus, performing exposure by scanning each of a plurality of scan fields included in a photosensitive substrate in a first direction with the pulse laser beam via a photomask in the exposure apparatus, heating the exposed photosensitive substrate so as to have a temperature distribution having a temperature gradient in a second direction intersecting the first direction on a surface of the photosensitive substrate in each of the scan fields, and supplying a developer to the surface of the photosensitive substrate to perform development after heating the photosensitive substrate.

### BRIEF DESCRIPTION OF THE DRAWINGS

Some embodiments of the present disclosure will be described below, by way of example only, with reference to the accompanying drawings.

FIG. 1 schematically illustrates a configuration of an exposure system in a comparative example.

FIG. 2 is a flowchart illustrating processing of forming a resist pattern on a photosensitive substrate in the comparative example.

FIG. 3 is a flowchart illustrating details of processing of post-exposure baking a photosensitive substrate and supplying a developer.

FIG. 4 schematically illustrates a configuration of a laser apparatus.

FIG. 5 illustrates a photosensitive substrate exposed by an exposure apparatus.

FIG. 6 is a diagram explaining how a position of a scan field of a photosensitive substrate changes with respect to a position of a beam cross section of a pulse laser beam.

FIG. 7 is a diagram explaining how a position of a scan field of a photosensitive substrate changes with respect to a position of a beam cross section of a pulse laser beam.

FIG. 8 is a diagram explaining how a position of a scan field of a photosensitive substrate changes with respect to a position of a beam cross section of a pulse laser beam.

FIG. 9 is a graph illustrating a periodic wavelength change.

FIG. 10 illustrates an integrated spectrum of a pulse laser beam including a plurality of center wavelengths.

FIG. 11 illustrates an example in which a wafer pattern different from a target pattern is formed by optical proximity when the target pattern is used as a mask pattern as it is.

FIG. 12 illustrates an example in which a wafer pattern close to a target pattern is formed when a corrected mask pattern to which optical proximity correction is performed is used.

FIG. 13 is a conceptual diagram of model-based OPC in the comparative example.

FIG. 14 is a flowchart of model-based OPC.

FIG. 15 illustrates a data structure of a measured wafer pattern.

FIG. 16 is a flowchart illustrating details of processing of creating a model function group.

FIG. 17 illustrates a concept of off-axis chromatic aberration generated when a photosensitive substrate is exposed to a pulse laser beam including a plurality of center wavelengths.

FIG. 18 illustrates how a contrast of an optical image formed on a photosensitive substrate is reduced by off-axis chromatic aberration.

FIG. 19 illustrates dimension measurement points for calculating line edge roughness.

FIG. 20 is a flowchart illustrating processing of forming a resist pattern on a photosensitive substrate in a first embodiment.

FIG. 21 is a flowchart illustrating details of processing of post-exposure baking a photosensitive substrate with a set temperature distribution and supplying a developer.

FIG. 22 is a flowchart illustrating details of processing of setting a temperature distribution for post-exposure baking.

FIG. 23 is a flowchart illustrating details of processing of post-exposure baking each of imax sheets of PEB test wafers and supplying a developer.

FIG. 24 illustrates PEB test wafers and temperatures set to post-exposure bake the PEB test wafers.

FIG. 25 is a flowchart illustrating details of processing of measuring a wafer pattern of imax sheets of developed PEB test wafers.

FIG. 26 conceptually illustrates regions where line edge roughness and a critical dimension are measured in a scan field.

FIG. 27 illustrates a table summarizing average values.

FIG. 28 is a flowchart illustrating details of processing of setting a temperature distribution based on a measurement result.

FIG. 29 illustrates an example of a temperature distribution in an X axis direction set in the first embodiment.

FIG. 30 illustrates an example of a temperature distribution in a Y axis direction set in the first embodiment.

FIG. 31 illustrates a first example of a temperature distribution set in the first embodiment.

FIG. 32 illustrates a second example of a temperature distribution set in the first embodiment.

FIG. 33 is a flowchart illustrating processing of forming a resist pattern on a photosensitive substrate in a second embodiment.

FIG. 34 is a flowchart illustrating details of processing of S13 in the second embodiment.

FIG. 35 is a flowchart illustrating details of processing of S15 in the second embodiment.

FIG. 36 is a conceptual diagram of divided model-based OPC in the second embodiment.

FIG. 37 illustrates a plurality of divided regions included in a scan field of a test wafer.

FIG. 38 is a flowchart of divided model-based OPC.

FIG. 39 illustrates a data structure of measured wafer patterns.

FIG. 40 is a flowchart illustrating details of processing of creating model function groups.

FIG. 41 illustrates an example of model function groups.

### DESCRIPTION OF EMBODIMENTS

### <Contents>

### 1. Comparative Example

1.1 Exposure System
   1.1.1 Configuration
   1.1.2 Operation
1.2 Laser Apparatus 100
   1.2.1 Configuration
   1.2.2 Operation
1.3 Line Narrowing Module 14
   1.3.1 Configuration
   1.3.2 Operation
1.4 Scan Exposure
1.5 Periodic Wavelength Change and Integrated Spectrum
1.6 Optical Proximity Correction (OPC)
   1.6.1 Overview
   1.6.2 Model-Based OPC
1.7 Problem of Comparative Example

### 2. Control of LER by Temperature Distribution of Post-Exposure Baking

2.1 Operation
   2.1.1 Post-Exposure Baking
   2.1.2 Setting of Temperature Distribution
2.2 Effect

### 3. Combination of Temperature Distribution of Post-Exposure Baking and OPC

3.1 Operation
3.2 Effect

### 4. Others

Hereinafter, embodiments of the present disclosure will be described in detail with reference to the drawings. The embodiments described below show some examples of the present disclosure and do not limit contents of the present disclosure. In addition, all configurations and operations described in the embodiments are not necessarily essential as configurations and operations of the present disclosure. Here, the same components are denoted by the same reference signs, and any redundant description thereof is omitted.

### 1. Comparative Example

### 1.1 Exposure System

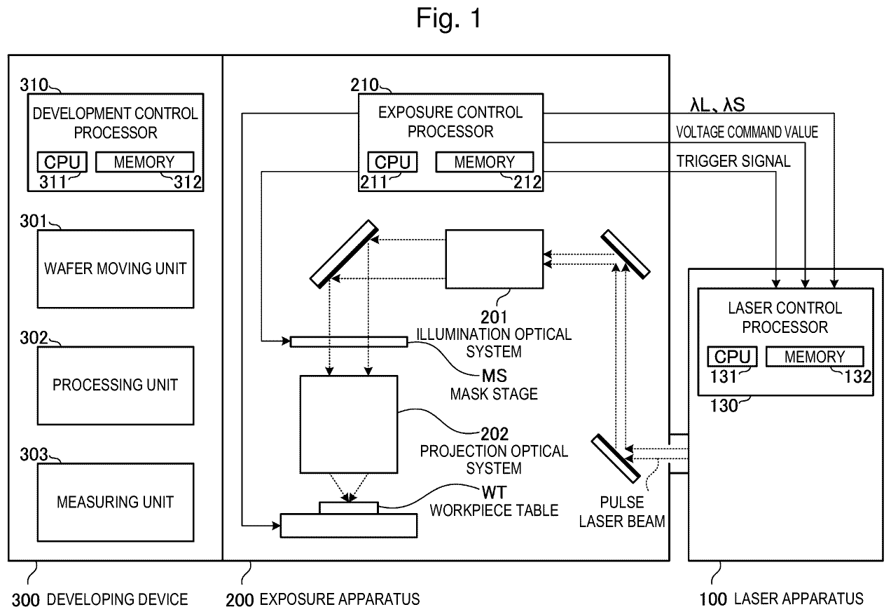

FIG. 1 schematically illustrates a configuration of an exposure system in a comparative example. The comparative example of the present disclosure is an example recognized by the applicant as known only by the applicant, and is not a publicly known example admitted by the applicant. The exposure system includes a laser apparatus 100, an exposure apparatus 200, and a developing device 300. In FIG. 1, the laser apparatus 100 is illustrated in a simplified manner.

The laser apparatus 100 includes a laser control processor 130. The laser control processor 130 is a processing device including a memory 132 in which a control program is stored, and a CPU (central processing unit) 131 which executes the control program. The laser control processor 130 is specifically configured or programmed to execute various kinds of processing included in the present disclosure. The laser apparatus 100 is configured to output a pulse laser beam toward the exposure apparatus 200.

### 1.1.1 Configuration

As illustrated in FIG. 1, the exposure apparatus 200 includes an illumination optical system 201, a projection optical system 202, and an exposure control processor 210.

The illumination optical system 201 illuminates a mask pattern of an unillustrated photomask disposed on a mask stage MS with the pulse laser beam that has entered from the laser apparatus 100.

The projection optical system 202 performs reduced projection of the pulse laser beam transmitted through the photomask, and forms an image on an unillustrated workpiece disposed on a workpiece table WT. The workpiece is a photosensitive substrate such as a semiconductor wafer on which a resist film is applied.

The exposure control processor 210 is a processing device including a memory 212 in which a control program is stored and a CPU 211 which executes the control program. The exposure control processor 210 is specifically configured or programmed to execute various kinds of processing included in the present disclosure. The exposure control processor 210 coordinates control of the exposure apparatus 200, and transmits and receives various kinds of parameters and various kinds of signals to and from the laser control processor 130.

The developing device 300 includes a wafer moving unit 301, a processing unit 302, a measuring unit 303, and a development control processor 310.

The wafer moving unit 301 is a device that transfers a photosensitive substrate to and from the exposure apparatus 200 and moves the photosensitive substrate inside the developing device 300.

The processing unit 302 is a device that performs coating of a resist film on a photosensitive substrate, post-exposure baking (PEB) of the photosensitive substrate exposed in the exposure apparatus 200, supplying of a developer, cleaning, drying, post-development baking (PDB), and the like. The post-exposure baking and the post-development baking are performed by heating the photosensitive substrate by an unillustrated hot plate included in the processing unit 302. A plurality of processing units 302 may be included in one developing device 300, and processing by each processing unit 302 may be performed in parallel.

The measuring unit 303 is a device such as a CD-SEM that measures a pattern formed on a photosensitive substrate by exposure and development. The measuring unit 303 may be included in the developing device 300 or may be provided separately from the developing device 300.

The development control processor 310 is a processing device including a memory 312 in which a control program is stored, and a CPU 311 which executes the control program. The development control processor 310 is specifically configured or programmed to execute various kinds of processing included in the present disclosure.

### 1.1.2 Operation

The exposure control processor 210 transmits various kinds of parameters including a target long wavelength λL, a target short wavelength λS, and a voltage command value, and a trigger signal to the laser control processor 130. The laser control processor 130 controls the laser apparatus 100 according to these parameters and signal.

The exposure control processor 210 synchronously translates the mask stage MS and the workpiece table WT in opposite directions. Thus, the workpiece is exposed to the pulse laser beam reflecting the mask pattern.

The mask pattern is transferred to the photosensitive substrate by such photolithography. Thereafter, an electronic device can be manufactured through a plurality of processes.

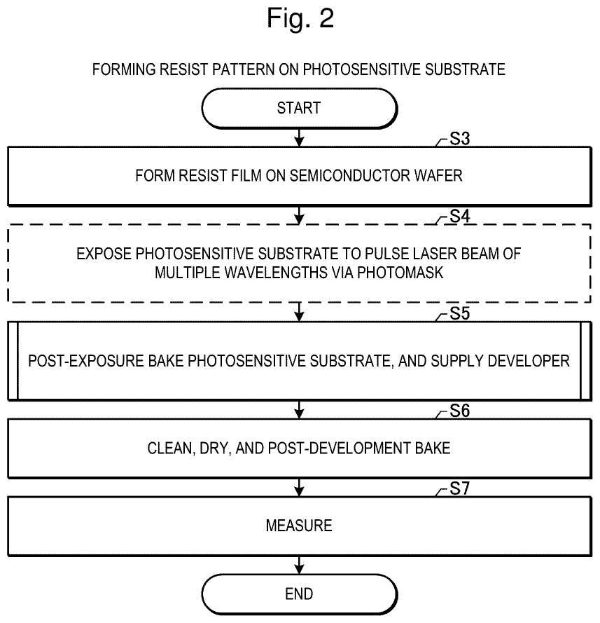

FIG. 2 is a flowchart illustrating processing of forming a resist pattern on a photosensitive substrate in the comparative example. Although FIG. 2 mainly illustrates the processing of the developing device 300, FIG. 2 also includes the processing of the exposure apparatus 200 in part.

In S3, the development control processor 310 controls the processing unit 302 to form a resist film on a semiconductor wafer to attain a photosensitive substrate.

In S4, the exposure control processor 210 controls each part of the exposure apparatus 200 to expose the photosensitive substrate to a pulse laser beam including a plurality of center wavelengths via a photomask.

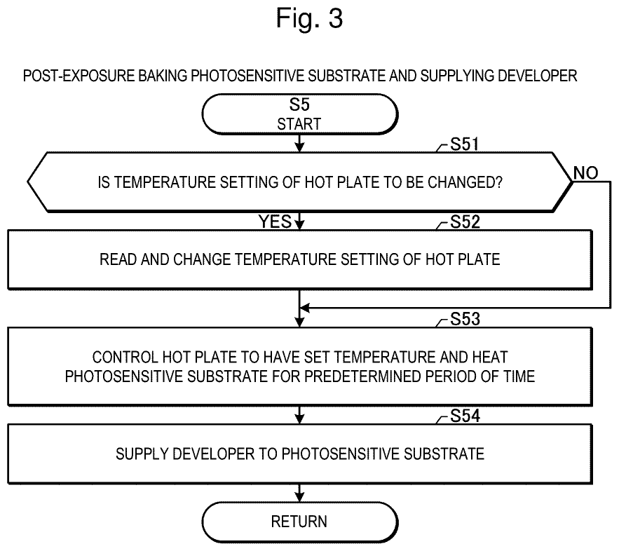

In S5, the development control processor 310 controls the processing unit 302 to post-exposure bake the photosensitive substrate and supply a developer to the photosensitive substrate. For example, acid generated at an exposed portion of the resist film serves as a catalyst during the post-exposure baking and accelerates chemical reaction of the resist film. By this chemical reaction, positive resist changes from alkali insoluble to alkali soluble, and negative resist changes from alkali soluble to alkali insoluble. Then, an alkali soluble portion is removed by an alkaline developer. Details of S5 will be described later with reference to FIG. 3.

In S6, the development control processor 310 controls the processing unit 302 to clean, dry, and post-development bake the developed photosensitive substrate.

In S7, the development control processor 310 controls the measuring unit 303 to measure the post-development baked photosensitive substrate as needed.

After S7, the processing of the present flowchart ends.

FIG. 3 is a flowchart illustrating details of processing of post-exposure baking a photosensitive substrate and supplying a developer. The processing illustrated in FIG. 3 corresponds to a subroutine of S5 in FIG. 2.

In S51, the development control processor 310 determines whether or not to change temperature setting of a hot plate. A temperature of the hot plate is determined by the mask pattern, the kind of resist, an exposure condition, and the like.

When the temperature setting of the hot plate is changed (S51: YES), the development control processor 310 reads new temperature setting and changes the temperature setting in S52.

When the temperature setting of the hot plate is not changed (S51: NO) or after the temperature setting of the hot plate is changed (S52), the development control processor 310 controls the processing unit 302 to bring the temperature of the hot plate close to a set temperature and to heat the photosensitive substrate for a predetermined period of time in S53.

In S54, the development control processor 310 controls the processing unit 302 to supply a developer to a surface of the photosensitive substrate.

After S54, the development control processor 310 ends the processing of the present flowchart and returns to the processing illustrated in FIG. 2.

### 1.2 Laser Apparatus 100

### 1.2.1 Configuration

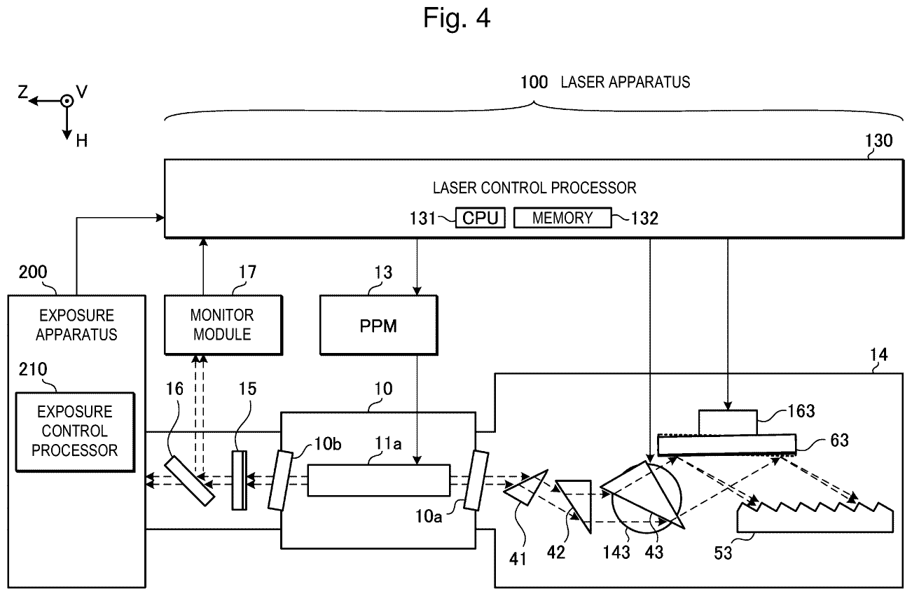

FIG. 4 schematically illustrates a configuration of the laser apparatus 100. FIG. 4 illustrates a V axis, an H axis, and a Z axis that are perpendicular to each other. In FIG. 4, the laser apparatus 100 viewed in a −V direction is illustrated, the exposure apparatus 200 is illustrated in a simplified manner, and the developing device 300 is not illustrated.

In addition to the laser control processor 130, the laser apparatus 100 includes a laser chamber 10, a pulse power module (PPM) 13, a line narrowing module 14, an output coupling mirror 15, and a monitor module 17. The line narrowing module 14 and the output coupling mirror 15 form an optical resonator.

The laser chamber 10 is disposed in an optical path of the optical resonator. The laser chamber 10 is provided with two windows 10a and 10b.

The laser chamber 10 includes a discharge electrode 11a and an unillustrated discharge electrode paired with the discharge electrode 11a. The unillustrated discharge electrode is positioned so as to overlap with the discharge electrode 11a in a direction of the V axis. The laser chamber 10 is filled with a laser gas containing, for example, an argon gas or a krypton gas as a rare gas, a fluorine gas as a halogen gas, and a neon gas as a buffer gas, or the like.

The pulse power module 13 includes an unillustrated switch, and is connected to an unillustrated charger.

The line narrowing module 14 includes prisms 41 to 43, a grating 53, and a mirror 63. Details of the line narrowing module 14 will be described later.

The output coupling mirror 15 is formed of a partial reflective mirror.

A beam splitter 16 that transmits a part of the pulse laser beam with a high transmittance and reflects the other part is disposed in an optical path of the pulse laser beam output from the output coupling mirror 15. The monitor module 17 is disposed in an optical path of the pulse laser beam reflected by the beam splitter 16.

### 1.2.2 Operation

The laser control processor 130 acquires various kinds of parameters including the target long wavelength λL, the target short wavelength λS, and the voltage command value from the exposure control processor 210. The laser control processor 130 transmits a control signal to the line narrowing module 14 based on the target long wavelength λL and the target short wavelength λS.

The laser control processor 130 receives the trigger signal from the exposure control processor 210. The laser control processor 130 transmits an oscillation trigger signal based on the trigger signal to the pulse power module 13. The switch included in the pulse power module 13 is turned to an ON state when the oscillation trigger signal is received from the laser control processor 130. When the switch is turned to the ON state, the pulse power module 13 generates a pulsed high voltage from electric energy charged in the charger, and applies the high voltage to the discharge electrode 11a.

When the high voltage is applied to the discharge electrode 11a, discharge occurs in a discharge space between the discharge electrode 11a and the unillustrated discharge electrode. By energy of the discharge, the laser gas in the laser chamber 10 is excited and shifts to a high energy level. When the excited laser gas then shifts to a low energy level, light having a wavelength corresponding to the energy level difference is discharged.

The light generated in the laser chamber 10 is output to an outside of the laser chamber 10 through the windows 10a and 10b. The light output from the window 10a enters the line narrowing module 14. Of the light that has entered the line narrowing module 14, light near a desired wavelength is turned back by the line narrowing module 14 and returned to the laser chamber 10.

The output coupling mirror 15 transmits and outputs a part of the light output from the window 10b, and reflects the other part back into the laser chamber 10.

In this way, the light output from the laser chamber 10 reciprocates between the line narrowing module 14 and the output coupling mirror 15. The light is amplified every time it passes through the discharge space in the laser chamber 10. Further, the light is narrowed every time it is turned back by the line narrowing module 14, and becomes light having a steep wavelength distribution with a part of a range of a selected wavelength by the line narrowing module 14 as a center wavelength. The light laser-oscillated and narrowed in this way is output as a pulse laser beam from the output coupling mirror 15.

The monitor module 17 measures the center wavelength of the pulse laser beam and notifies the laser control processor 130 of a measured wavelength. The laser control processor 130 feedback-controls the line narrowing module 14 based on the measured wavelength.

The pulse laser beam transmitted through the beam splitter 16 enters the exposure apparatus 200.

### 1.3 Line Narrowing Module 14

### 1.3.1 Configuration

The prisms 41 to 43 are disposed in an optical path of a light beam output from the window 10a in an order from the smallest of the reference numerals of these prisms. The prisms 41 to 43 are disposed such that surfaces of the prisms 41 to 43 where the light beam enters and is output are all parallel to the V axis. The prism 43 is rotatable about an axis parallel to the V axis by a rotating stage 143.

The mirror 63 is disposed in an optical path of the light beam transmitted through the prisms 41 to 43. The mirror 63 is disposed such that a surface that reflects the light beam is parallel to the V axis, and is rotatable about an axis parallel to the V axis by a rotating stage 163.

The grating 53 is disposed in an optical path of the light beam reflected by the mirror 63. A direction of grooves of the grating 53 is parallel to the V axis.

### 1.3.2 Operation

Each of the prisms 41 to 43 changes a traveling direction of the light beam output from the window 10a in a plane parallel to an HZ plane perpendicular to the V axis, and expands a beam width in the plane parallel to the HZ plane.

The light beam transmitted through the prisms 41 to 43 is reflected by the mirror 63 and enters the grating 53.

The light beam incident on the grating 53 is reflected by the grooves of the grating 53 and is diffracted in a direction corresponding to the wavelength of the light. The grating 53 is disposed in Littrow arrangement such that an incident angle of the light beam from the mirror 63 onto the grating 53 coincides with a diffracting angle of diffracted light of a desired wavelength.

The mirror 63 and the prisms 41 to 43 reduce the beam width of the light beam returned from the grating 53 in the plane parallel to the HZ plane, and return the light beam to the inside of the laser chamber 10 through the window 10a.

The laser control processor 130 controls the rotating stages 143 and 163 via an unillustrated driver. In accordance with rotation angles of the rotating stages 143 and 163, the incident angle of the light beam on the grating 53 changes, and the wavelength selected by the line narrowing module 14 changes. The rotating stage 143 is mainly used for coarse adjustment, and the rotating stage 163 is mainly used for fine adjustment.

The laser control processor 130 controls the rotating stage 163 such that a posture of the mirror 63 periodically changes for each of a plurality of pulses, based on the target long wavelength λL and the target short wavelength λS received from the exposure control processor 210. Thus, the center wavelength of the pulse laser beam periodically changes between the target long wavelength λL and the target short wavelength λS for each of the pulses. In this way, the laser apparatus 100 can perform laser oscillation at multiple wavelengths.

A focal length in the exposure apparatus 200 depends on the wavelength of the pulse laser beam. Since the pulse laser beam that is laser-oscillated at the multiple wavelengths and enters the exposure apparatus 200 can be imaged at a plurality of different positions in the direction of an optical path axis of the pulse laser beam, a focal depth can be substantially increased. For example, even when a resist film having a large thickness is exposed, imaging performance in a thickness direction of the resist film can be maintained. Alternatively, a resist profile indicating a cross-sectional shape of the developed resist film can be adjusted.

### 1.4 Scan Exposure

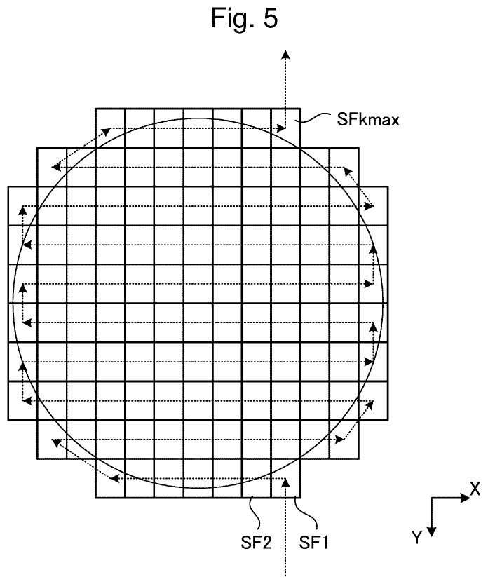

FIG. 5 illustrates a photosensitive substrate exposed by the exposure apparatus 200. The photosensitive substrate is, for example, a single crystal silicon plate having a substantially disk shape. The photosensitive substrate is exposed for each section of scan fields SF1, SF2, and others. Each of the scan fields SF1 and SF2 corresponds to a region where several semiconductor chips of many semiconductor chips formed on the photosensitive substrate are formed, and a reticle pattern of one reticle is transferred by scanning of one time. Numbers included in the signs SF1 and SF2 indicate an exposure order. When descriptions are given without specifying the exposure order, the scan field is simply denoted as SF without any number added.

First, the photosensitive substrate is moved such that the first scan field SF1 is irradiated with the pulse laser beam, and the first scan field SF1 is exposed.

Next, the photosensitive substrate is moved such that the second scan field SF2 is irradiated with the pulse laser beam, and the second scan field SF2 is exposed.

The other scan fields SF are also sequentially exposed, and when a last scan field SFkmax is exposed, exposure of the photosensitive substrate ends.

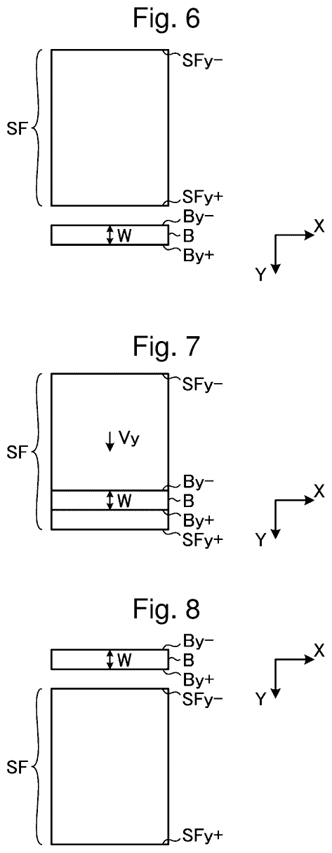

FIG. 6 to FIG. 8 illustrate how a position of the scan field SF of the photosensitive substrate changes with respect to a position of a beam cross section B of the pulse laser beam. A direction in which the position of the scan field SF changes is defined as a Y axis direction, and a direction perpendicular to the Y axis direction is defined as an X axis direction. The Y axis direction corresponds to a first direction in the present disclosure, and the X axis direction corresponds to a second direction in the present disclosure.

When one scan field SF is exposed, the pulse laser beam is continuously output at a predetermined repetition frequency. Continuous output of the pulse laser beam at the predetermined repetition frequency is referred to as burst output. When an exposure position is moved from one scan field SF to another scan field SF, output of the pulse laser beam is stopped. Thus, the burst output is repeated multiple times to expose one photosensitive substrate.

A width in the X axis direction of the scan field SF corresponds to a width in the X axis direction of the beam cross section B of the pulse laser beam at a position of the workpiece table WT (see FIG. 1). A width in the Y axis direction of the scan field SF is larger than a width W in the Y axis direction of the beam cross section B of the pulse laser beam at the position of the workpiece table WT.

A procedure of scanning and exposing each scan field SF in the Y axis direction with the pulse laser beam is performed in the order of FIG. 6, FIG. 7, and FIG. 8. First, as illustrated in FIG. 6, the workpiece table WT is positioned such that an end SFy+ in a +Y direction of the scan field SF is positioned away from a position of an end By− in a −Y direction of the beam cross section B by a predetermined distance in the −Y direction. Then, the workpiece table WT is accelerated in the +Y direction so as to be a velocity Vy before the end SFy+ in the +Y direction of the scan field SF coincides with the position of the end By− in the −Y direction of the beam cross section B. As illustrated in FIG. 7, the scan field SF is exposed while the workpiece table WT is moved in the +Y direction such that the position of the scan field SF moves uniformly and linearly at the velocity Vy with respect to the position of the beam cross section B. As illustrated in FIG. 8, when the workpiece table WT is moved until the end SFy− in the −Y direction of the scan field SF passes the position of the end By+ in the +Y direction of the beam cross section B, the scanning of the scan field SF ends.

In this way, the exposure is performed while the scan field SF moves with respect to the position of the beam cross section B. When the scan field SF is used as a reference, it can be said that the scanning is performed in the −Y direction with the pulse laser beam.

Required time Ts for the scan field SF to move a distance corresponding to the width W of the beam cross section B of the pulse laser beam at the velocity Vy is as follows.

$$Ts = W / Vy$$

An irradiation pulse number Ns of the pulse laser beam with which an arbitrary part of the scan field SF is irradiated is same as a pulse number of the pulse laser beam generated during the required time Ts, and is as follows.

$$Ns = F \cdot Ts$$

Here, F is the repetition frequency of the pulse laser beam.

The irradiation pulse number Ns is also referred to as an N slit pulse number.

While the scan field SF included in the photosensitive substrate for manufacturing an electronic device has been described here, the same applies to the scan field SF included in a PEB test wafer and an OPC test wafer to be described later.

### 1.5 Periodic Wavelength Change and Integrated Spectrum

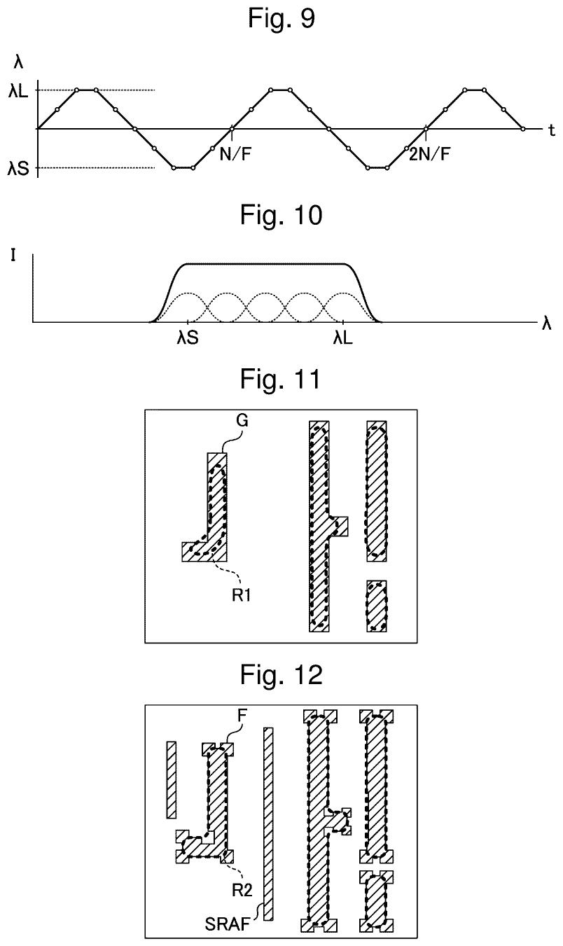

FIG. 9 is a graph illustrating a periodic wavelength change. In FIG. 9, a horizontal axis represents time t and a vertical axis represents a wavelength k. Each of small circles illustrated in FIG. 9 indicates the time t when the pulse laser beam is output and the center wavelength at that time.

In an example illustrated in FIG. 9, the center wavelength periodically changes between the target long wavelength λL and the target short wavelength λS. The pulse number for one period of the wavelength change is defined as N. A period T of the wavelength change is given by an equation below.

$$T = N / F$$

FIG. 10 illustrates an integrated spectrum of the pulse laser beam including the center wavelengths. The integrated spectrum illustrated in FIG. 10 corresponds to an integrated spectrum for one period of the wavelength change illustrated in FIG. 9. In FIG. 10, a horizontal axis represents the wavelength k and a vertical axis represents light intensity I. A dashed line represents a spectrum of the pulse laser beam for each pulse, and each center wavelength may coincide with a peak wavelength. By changing the center wavelength in multiple stages between the target long wavelength λL and the target short wavelength λS as illustrated in FIG. 9, the integrated spectrum illustrated in FIG. 10 can be a flat top shape having substantially uniform light intensity I between the target long wavelength λL and the target short wavelength λS.

The irradiation pulse number Ns of the pulse laser beam with which an arbitrary part of the scan field SF is irradiated is preferably a multiple of the pulse number N for one period of the wavelength change. As a result, any part of the scan field SF is irradiated with the pulse laser beam of the irradiation pulse number Ns having the same integrated spectrum. Thus, it is possible to manufacture a high-quality electronic device with little variation in an exposure result depending on an irradiation position.

### 1.6 Optical Proximity Correction (OPC)

### 1.6.1 Overview

In photolithography, when a dimension of a designed target pattern G becomes smaller than a wavelength of an exposure light source, even if the target pattern G is drawn on a mask as it is and exposed, a wafer pattern equivalent to the target pattern G may not be obtained. Therefore, creating a corrected mask pattern F by correcting the target pattern G in advance so as to obtain a wafer pattern equivalent to the target pattern G is referred to as optical proximity correction (OPC).

FIG. 11 illustrates an example in which a wafer pattern R1 different from the target pattern G is formed by optical proximity when the target pattern G is used as a mask pattern as it is. For example, influences are seen in that corner portions included in the target pattern G are rounded in the wafer pattern R1, or projected portions included in the target pattern G are retracted in the wafer pattern R1.

FIG. 12 illustrates an example in which a wafer pattern R2 close to the target pattern G is formed when the corrected mask pattern F to which the optical proximity correction is performed is used. The corrected mask pattern F includes deformations of adding overhang portions at projected corner portions in the target pattern G, further providing dent-like corner portions in the target pattern G, and adding an assist pattern SRAF (sub-resolution assist feature), for example. Thus, the wafer pattern R2 in a shape close to the target pattern G can be obtained.

In the optical proximity correction, not only the optical proximity is corrected but also differences between the mask pattern and the wafer pattern generated in development of the resist film and other semiconductor processes can be corrected together.

As the optical proximity correction, two types that are model-based OPC and rule-based OPC are known. Here, the model-based OPC will be described as an example.

### 1.6.2 Model-Based OPC

In the model-based OPC, a model function group M is created based on a result of an exposure simulation performed for each characteristic shape included in the target pattern G and an actual exposure result. Using the model function group M, the corrected mask pattern F for obtaining a wafer pattern equivalent to the target pattern G is created. The model-based OPC is used mainly in linewidth generations smaller than 130 nm.

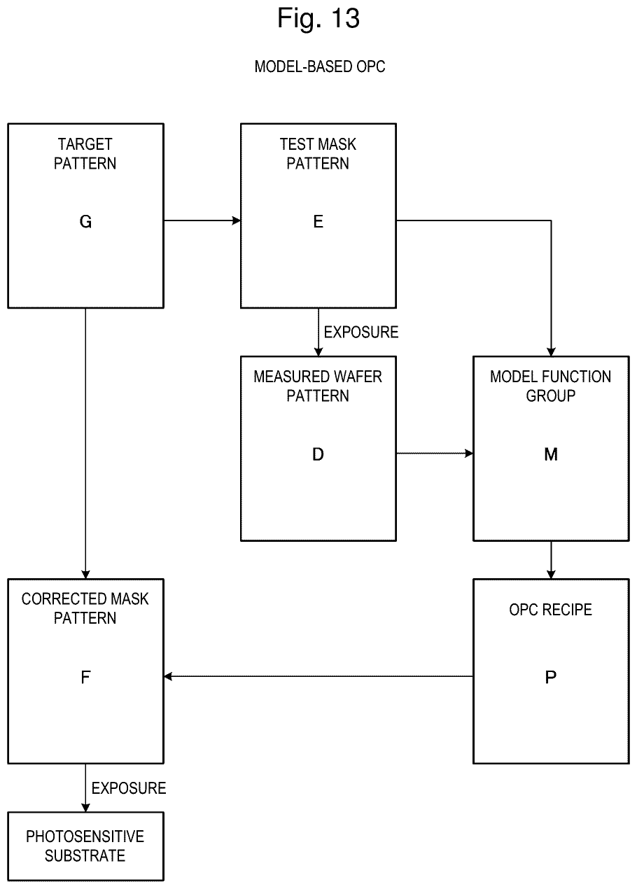

FIG. 13 is a conceptual diagram of the model-based OPC in the comparative example. First, an OPC test mask including a test mask pattern E is created based on the target pattern G. An OPC test wafer is exposed using the OPC test mask, and a patterned OPC test wafer is measured to acquire a measured wafer pattern D.

Based on the result of the exposure simulation using the test mask pattern E and the measured wafer pattern D which is the actual exposure result, the model function group M for predicting the actual exposure result from the result of the exposure simulation is created. Using the model function group M, an OPC recipe P, which is a program for creating the corrected mask pattern F from the target pattern G, is created. By executing the OPC recipe P using the target pattern G, the corrected mask pattern F is created. By exposing the photosensitive substrate using the corrected mask pattern F, a wafer pattern close to the target pattern G can be obtained.

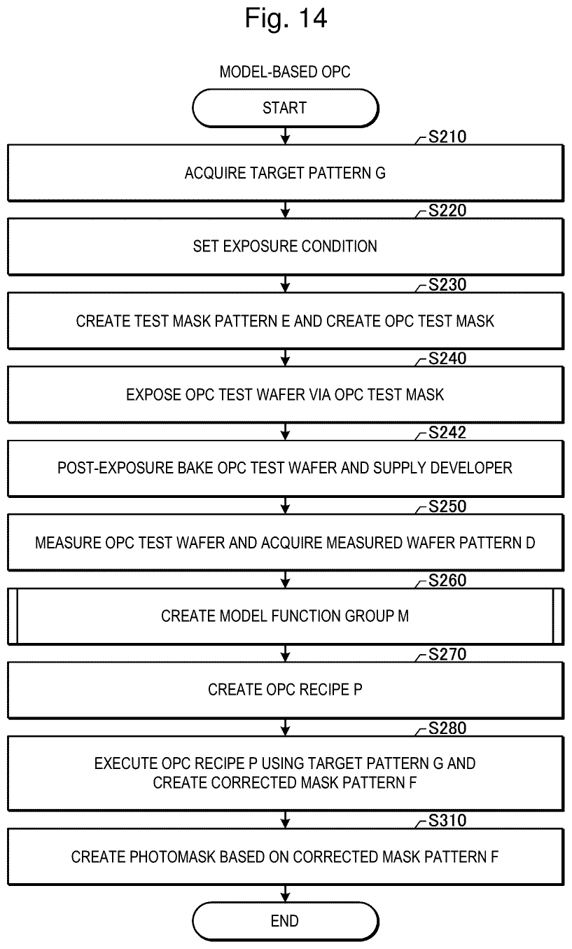

FIG. 14 is a flowchart of the model-based OPC. Processing illustrated in FIG. 14 is performed by a processor such as the exposure control processor 210, for example. The processor may be included in another device such as an unillustrated mask manufacturing device or an unillustrated server connected to a plurality of exposure apparatuses 200, and a configuration of such a processor may be the same as that of the exposure control processor 210. In a case where computational complexity is enormous, it is advantageous to increase throughput of the processor included in the server rather than to individually increase throughput of the exposure control processor 210 included in the exposure apparatuses 200.

In S210, the processor acquires the target pattern G. The target pattern G is a target wafer pattern of a photosensitive substrate designed by a semiconductor chip designer, and is provided in a data format called, for example, GDS (Graphic Data System) or OASIS (Open Artwork System Interchange Standard). The target pattern G may be a pattern after etching when etching of the photosensitive substrate is to be performed, or may be a pattern of a resist film developed after exposure when etching is not to be performed.

In S220, the processor sets an exposure condition based on the target pattern G. The exposure condition includes a setting condition of the exposure apparatus 200, for example, a shape of an illumination light source by the illumination optical system 201 (see FIG. 1), presence or absence of polarized illumination, and a numerical aperture of the projection optical system 202. Further, for example, the exposure condition includes the kind of the resist film, the presence or absence and the kind of an anti-reflective film, resist stack information, a film thickness of the resist film, a coating condition of the resist film, and a development condition.

In S230, the processor creates the test mask pattern E based on the target pattern G. Specifically, the characteristic shapes included in the target pattern G are extracted, and one or more dimensional conditions are set for each shape to form the test mask pattern E.

An OPC test mask is created by a mask manufacturing device according to the test mask pattern E.

In S240, the exposure apparatus 200 scans an OPC test wafer via the OPC test mask to expose the OPC test wafer. The OPC test wafer is a test exposure substrate coated with a resist film under the same conditions as the photosensitive substrate. The OPC test mask corresponds to a second test mask in the present disclosure, and the OPC test wafer corresponds to a second test wafer in the present disclosure.

In S242, the processor controls the processing unit 302 to post-exposure bake the OPC test wafer in the developing device 300 and to supply a developer to a surface of the OPC test wafer.

Further, the developed photosensitive substrate is cleaned, dried, and post-development baked, and when etching is to be performed, an unillustrated etching device performs etching to pattern the OPC test wafer.

In S250, the processor measures a wafer pattern of the OPC test wafer by an unillustrated measuring device such as a CD-SEM, and acquires the measured wafer pattern D indicating the measurement result.

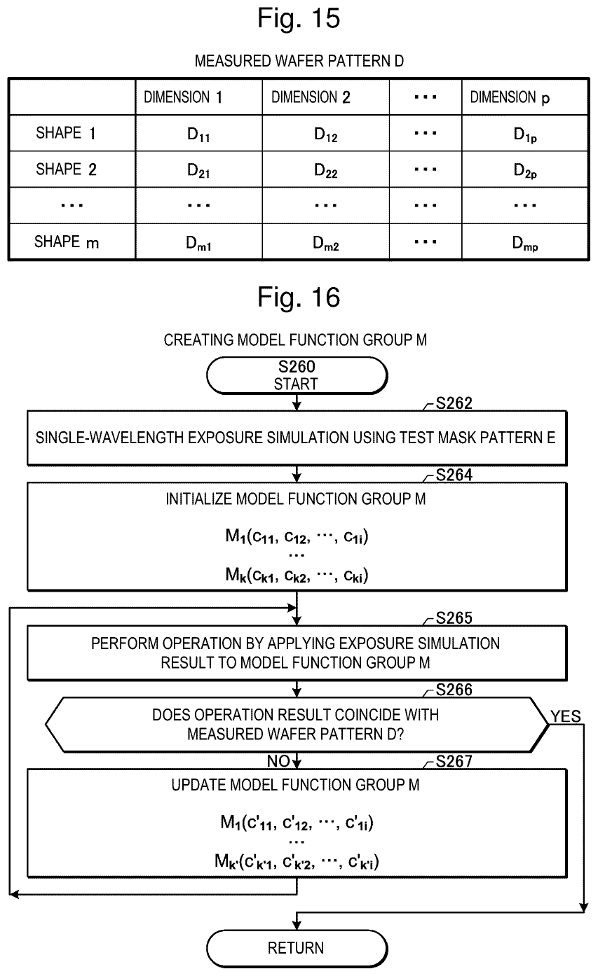

FIG. 15 illustrates a data structure of the measured wafer pattern D. The measured wafer pattern D includes p pieces of dimensions measured for each of m pieces of shapes 1 to m. For example, dimensions D₁₁ to D₁ₚ are measured for the shape 1, dimensions D₂₁ to D₂ₚ are measured for the shape 2, and dimensions Dₘ₁ to Dₘₚ is measured for the shape m. However, a value of p in the shapes 1 to m may be different from each other, and the value of p may be 1, 2, or more.

When test exposure is performed on the scan fields SF included in the OPC test wafer using one OPC test mask, average values for each shape and for each dimension are calculated from measurement results in the scan fields SF to attain the measured wafer pattern D.

Referring back to FIG. 14, in S260, the processor creates the model function group M based on the test mask pattern E and the measured wafer pattern D.

FIG. 16 is a flowchart illustrating details of processing of creating the model function group M. The processing illustrated in FIG. 16 corresponds to a subroutine of S260 in FIG. 14.

In S262, the processor performs a single-wavelength exposure simulation using the test mask pattern E. In the exposure simulation, Fourier imaging theory is used.

In S264, the processor initializes the model function group M. The model function group M includes, for example, k pieces of functions M₁ to Mₖ. Each of the functions M₁ to Mₖ includes a plurality of coefficients. For example, the function M₁ includes i pieces of coefficients c₁₁ to c₁ᵢ, and the function Mₖ includes i pieces of coefficients cₖ₁ to cₖᵢ. However, the value of i in the functions M₁ to Mₖ may be different from each other.

In S265, the processor performs a predictive operation of a wafer pattern by applying an exposure simulation result to the model function group M. The predictive operation includes four arithmetic operations and convolution integration.

In S266, the processor determines whether or not a result of the predictive operation coincides with the measured wafer pattern D. Even if the result of the predictive operation does not completely coincide with the measured wafer pattern D, it can be determined that the result of the predictive operation coincides with the measured wafer pattern D when a predetermined condition is satisfied. When the result of the predictive operation coincides with the measured wafer pattern D (S266: YES), the processor defines the model function group M used in S265 as the created model function group M, ends the processing of the present flowchart, and returns to the processing illustrated in FIG. 14. When the result of the predictive operation does not coincide with the measured wafer pattern D (S266: NO), the processor advances the processing to S267.

In S267, the processor updates the model function group M by changing the coefficients included in the model function group M and performing other modifications. The updated model function group M includes, for example, k′ pieces of functions M₁ to M_{k′}. A value of k′ indicating the number of the functions M₁ to M_{k′} may be different from the number of the functions M₁ to Mₖ included in the model function group M used in S265. Coefficients c′₁₁ to c′_{k′i} included in the functions M₁ to M_{k′} may also be different from the coefficients c₁₁ to cₖᵢ included in the model function group M used in S265.

After S267, the processor returns the processing to S265 and updates the model function group M until the result of the predictive operation coincides with the measured wafer pattern D.

Referring back to FIG. 14, in S270, the processor creates the OPC recipe P based on the model function group M. The OPC recipe P includes, for example, descriptions regarding a definition of the model function group M, a measurement point and a measurement direction of the dimensions D₁₁ to Dₘₚ illustrated in FIG. 15, and a correction rule of the mask pattern.

In S280, the processor executes the OPC recipe P using the target pattern G to create the corrected mask pattern F. The corrected mask pattern F is also provided in the GDS or OASIS data format.

In S310, the mask manufacturing device creates a photomask based on the corrected mask pattern F, and ends the processing of the present flowchart.

### 1.7 Problem of Comparative Example

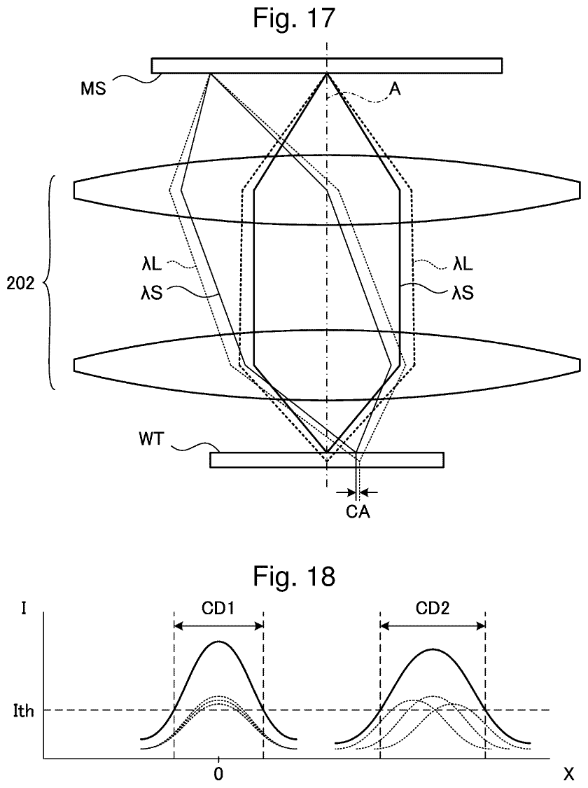

FIG. 17 illustrates off-axis chromatic aberration CA generated when a photosensitive substrate is exposed to a pulse laser beam including a plurality of center wavelengths. As illustrated in FIG. 17, since a refractive index in the projection optical system 202 is different between the target long wavelength λL and the target short wavelength λS, the part of the mask pattern of the mask disposed on the mask stage MS, the part being located on an optical path axis A of the projection optical system 202, is imaged at a position different in a depth direction of the photosensitive substrate disposed on the workpiece table WT. This is called on-axis chromatic aberration. On the other hand, the part of the mask pattern positioned away from the optical path axis A is imaged at a position different not only in the depth direction of the photosensitive substrate but also in a surface direction of the photosensitive substrate. This is called the off-axis chromatic aberration CA.

FIG. 18 illustrates how a contrast of an optical image formed on a photosensitive substrate is reduced by the off-axis chromatic aberration. In FIG. 18, a horizontal axis represents a distance in the X axis direction from a position 0 of the optical path axis A, and a vertical axis represents the light intensity I.

The light of the multiple wavelengths having light intensity distributions indicated by broken lines is imaged at the same position in the X axis direction at the position 0 of the optical path axis A, while at a position away from the optical path axis A, since the light of different wavelengths is imaged at different positions in the X axis direction, the light intensity distribution indicated by a solid line obtained by synthesizing the light of those wavelengths is long in the X axis direction. When a critical dimension is a width of a part exposed with the light intensity I equal to or higher than a threshold Ith, a critical dimension CD2 at the position away from the optical path axis A is larger than a critical dimension CD1 at the position 0 of the optical path axis A. Further, at the position away from the optical path axis A, an inclination of the light intensity I near the threshold Ith becomes gentle. As a result, the contrast of the optical image formed on the photosensitive substrate is reduced at the position away from the optical path axis A.

When the contrast is reduced, line edge roughness (LER) of a pattern formed by post-exposure development may be deteriorated.

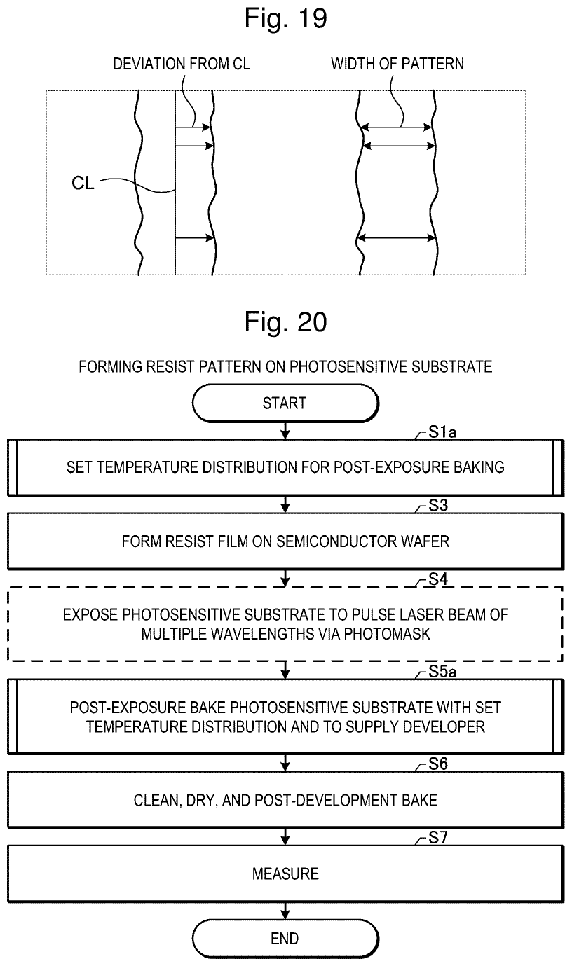

FIG. 19 illustrates dimension measurement points for calculating the line edge roughness. The line edge roughness is evaluated by a root mean square (RMS) of a deviation from an ideal center line CL to an edge, for example, and becomes larger as dispersion increases. Therefore, smaller line edge roughness is desirable.

The line edge roughness may be evaluated by the width of the pattern instead of being evaluated by the deviation from the ideal center line CL to the edge, or may be evaluated by a standard deviation instead of the root mean square. An index evaluated by the width of the pattern may be referred to as line width roughness (LWR), and is collectively referred to as the line edge roughness in the present specification.

Embodiments described below relate to suppressing deterioration of the line edge roughness caused by magnification chromatic aberration when exposure is performed using multiple wavelengths.

### 2. Control of LER by Temperature Distribution of Post-Exposure Baking

### 2.1 Operation

FIG. 20 is a flowchart illustrating processing of forming a resist pattern on a photosensitive substrate in a first embodiment. Although FIG. 20 mainly illustrates the processing of the developing device 300, FIG. 20 also includes the processing of the exposure apparatus 200 in part.

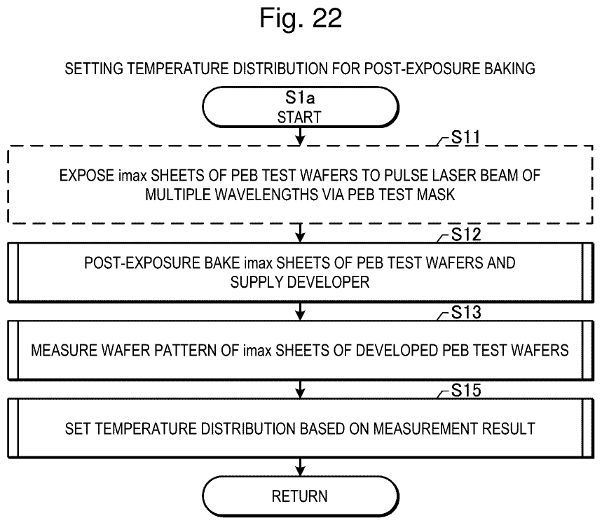

In S1a, the development control processor 310 sets a temperature distribution for the post-exposure baking. The temperature distribution for the post-exposure baking has a temperature gradient in the X axis direction in each of the scan fields SF. Details of the processing in S1a will be described later with reference to FIG. 22.

S3 and S4 after S1a are similar to those described with reference to FIG. 2.

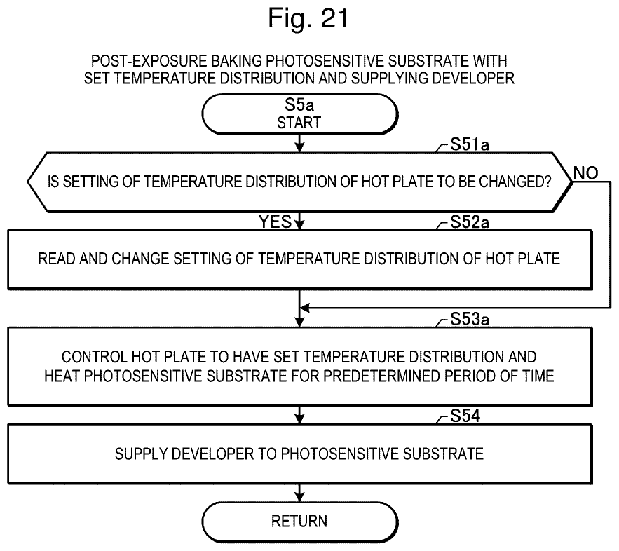

In S5a, the development control processor 310 controls the processing unit 302 to post-exposure bake the photosensitive substrate with the set temperature distribution and to supply a developer to the surface of the photosensitive substrate. Details of S5a will be described later with reference to FIG. 21.

S6 and S7 after S5a are similar to those described with reference to FIG. 2.

### 2.1.1 Post-Exposure Baking

FIG. 21 is a flowchart illustrating details of processing of post-exposure baking a photosensitive substrate with a set temperature distribution and supplying a developer. The processing illustrated in FIG. 21 corresponds to a subroutine of S5a in FIG. 20, and is similar to that described with reference to FIG. 3, except that the temperature distribution having the temperature gradient in the X axis direction is set instead of setting the temperature of the entire hot plate.

### 2.1.2 Setting of Temperature Distribution

FIG. 22 is a flowchart illustrating details of processing of setting a temperature distribution for post-exposure baking. The processing illustrated in FIG. 22 corresponds to a subroutine of S1a in FIG. 20. The temperature distribution for the post-exposure baking may be set in advance according to a combination of the mask pattern, the kind of resist, the exposure condition, and the like, and required setting data may be read out in S5a.

Before the development control processor 310 sets the temperature distribution, the exposure control processor 210 controls, in S11, each part of the exposure apparatus 200 to expose imax sheets of PEB test wafers to the pulse laser beam including the center wavelengths via a PEB test mask. The PEB test mask may be specially designed to set the temperature distribution for the post-exposure baking, or may be similar to the photomask used in S4 in FIG. 20. Each of the imax sheets of PEB test wafers is similar to the photosensitive substrate used in S4 in FIG. 20, and each of the scan fields SF is scanned in the Y axis direction by the exposure apparatus 200. The imax sheets may be, for example, in a range of 3 to 10 sheets. The PEB test mask corresponds to a first test mask in the present disclosure, and the PEB test wafer corresponds to a first test wafer in the present disclosure.

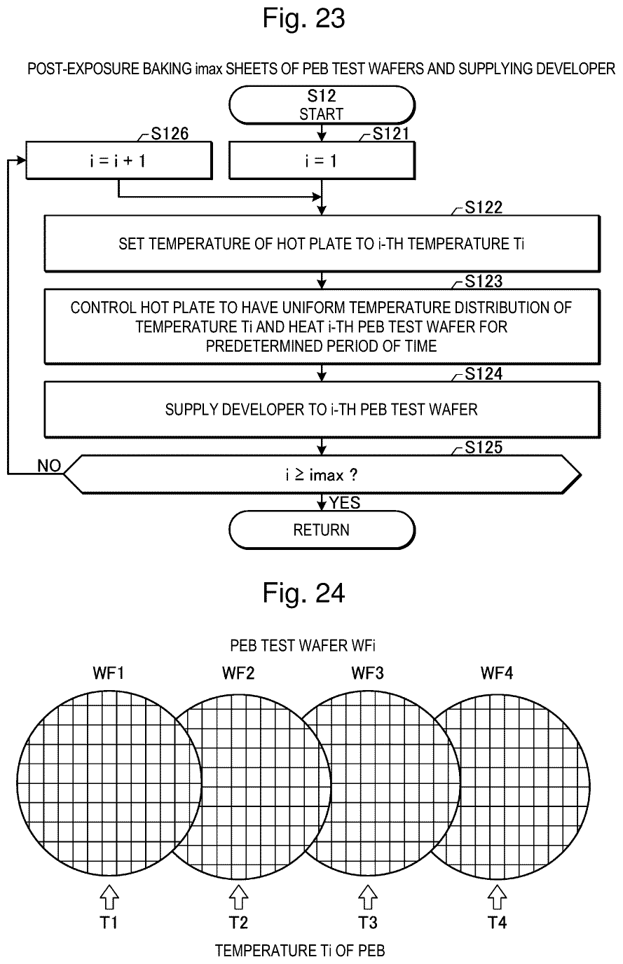

In S12, the development control processor 310 controls the processing unit 302 to post-exposure bake the imax sheets of PEB test wafers and to supply a developer to the surface of the PEB test wafers. Details of S12 will be described later with reference to FIG. 23.

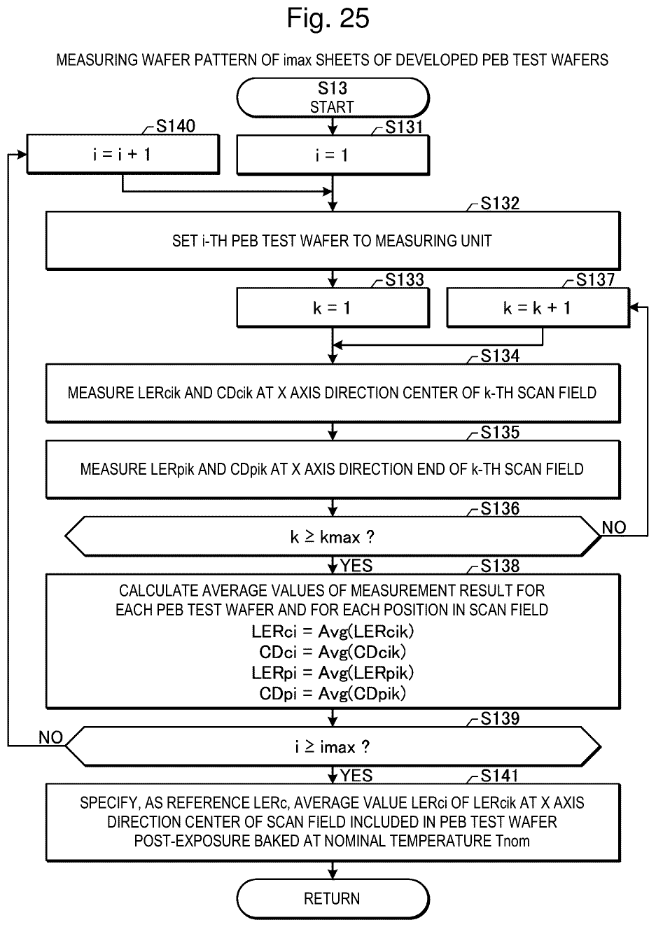

In S13, the development control processor 310 controls the measuring unit 303 to measure the wafer pattern of the imax sheets of developed PEB test wafers. Details of S13 will be described later with reference to FIG. 25.

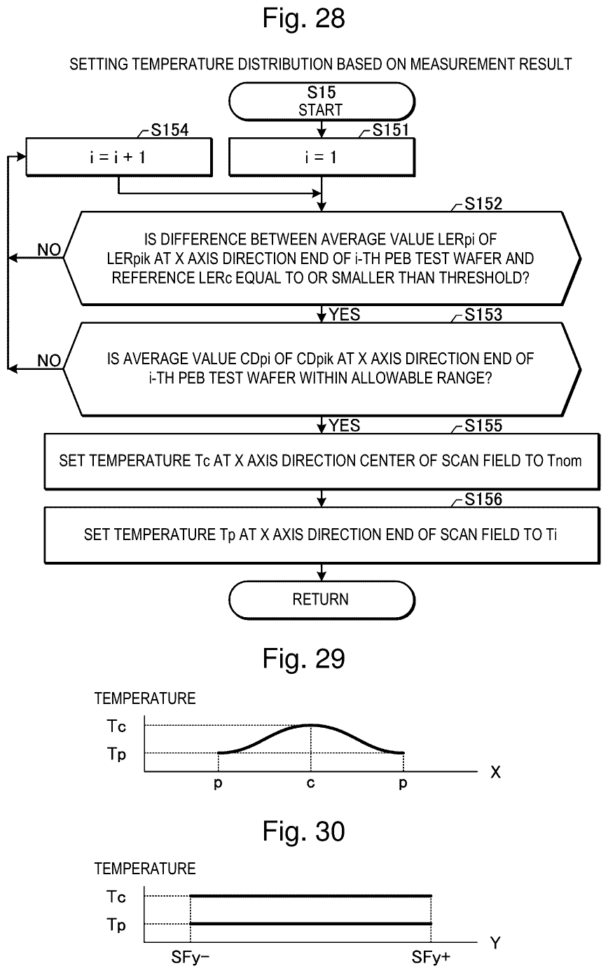

In S15, the development control processor 310 sets the temperature distribution based on the measurement result. Details of S15 will be described later with reference to FIG. 28.

After S15, the development control processor 310 ends the processing of the present flowchart and returns to the processing illustrated in FIG. 20.

FIG. 23 is a flowchart illustrating details of processing of post-exposure baking each of imax sheets of PEB test wafers and supplying a developer. The processing illustrated in FIG. 23 corresponds to a subroutine of S12 in FIG. 22.

In S121, the development control processor 310 sets a counter i for counting the imax sheets of PEB test wafers to 1. The imax sheets of PEB test wafers are heated at different temperatures T1 to Timax. The temperature of the hot plate for heating an i-th PEB test wafer WFi is defined as an i-th temperature T1. The temperatures T1 to Timax are set at a predetermined temperature interval with a nominal temperature Tnom as a center. The nominal temperature Tnom is an optimum temperature for the post-exposure baking derived without considering the magnification chromatic aberration, and corresponds to a reference temperature in the present disclosure. The predetermined temperature interval is, for example, 2° C. or higher and 10° C. or lower.

In S122, the development control processor 310 sets the temperature of the hot plate to the i-th temperature T1.

In S123, the development control processor 310 controls the processing unit 302 to control the hot plate to have a uniform temperature distribution of the temperature T1 and to heat the i-th PEB test wafer WFi for a predetermined period of time.

In S124, the development control processor 310 controls the processing unit 302 to supply a developer to a surface of the i-th PEB test wafer WFi.

In S125, the development control processor 310 determines whether or not a value of the counter i has reached imax. When the value of the counter i has not reached imax (S125: NO), the development control processor 310 adds 1 to the value of the counter i in S126, and returns the processing to S122. Accordingly, the next PEB test wafer is post-exposure baked at a different temperature T1 and developed.

When the value of the counter i has reached imax (S125: YES), the development control processor 310 ends the processing of the present flowchart and returns to the processing illustrated in FIG. 22.

FIG. 24 illustrates PEB test wafers WF1 to WF4 and the temperature T1 set to post-exposure bake the PEB test wafers WF1 to WF4. As the temperature Ti, only one value is set for one PEB test wafer WFi.

FIG. 25 is a flowchart illustrating details of processing of measuring a wafer pattern of imax sheets of developed PEB test wafers. The processing illustrated in FIG. 25 corresponds to a subroutine of S13 in FIG. 22.

In S131, the development control processor 310 sets the counter i for counting the imax sheets of PEB test wafers to 1.

In S132, the development control processor 310 controls the wafer moving unit 301 to set the i-th PEB test wafer WFi in the measuring unit 303.

In S133, the development control processor 310 sets a counter k for counting the scan fields SF to 1.

In S134, the development control processor 310 controls the measuring unit 303 to measure line edge roughness LERcik and a critical dimension CDcik at an X axis direction center of a k-th scan field SFk of the i-th PEB test wafer WFi.

In S135, the development control processor 310 controls the measuring unit 303 to measure line edge roughness LERpik and a critical dimension CDpik at an X axis direction end of the k-th scan field SFk of the i-th PEB test wafer WFi. A position of the X axis direction end of the scan field SFk corresponds to a first position in the present disclosure.

In S136, the development control processor 310 determines whether or not a value of the counter k has reached kmax. When the value of the counter k has not reached kmax (S136: NO), the development control processor 310 adds 1 to the value of the counter k in S137, and returns the processing to S134. When the value of the counter k has reached kmax (S136: YES), the development control processor 310 advances the processing to S138.

In S138, the development control processor 310 calculates and stores average values LERci, CDci, LERpi, and CDpi of the measurement results for each PEB test wafer WFi and for each position in the scan field by equations below.

LERci=Avg(LERcik)

CDci=Avg(CDcik)

LERpi=Avg(LERpik)

CDpi=Avg(CDpik)

Here, Avg(Xik) is an average value of kmax pieces of Xik values.

In S139, the development control processor 310 determines whether or not the value of the counter i has reached imax. When the value of the counter i has not reached imax (S139: NO), the development control processor 310 adds 1 to the value of the counter i in S140, and returns the processing to S132. When the counter i has reached imax (S139: YES), the development control processor 310 advances the processing to S141.

In S141, the development control processor 310 specifies, as a reference LERc, the average value LERci of the line edge roughness LERcik at the X axis direction center of the scan field SF included in the PEB test wafer post-exposure baked at the nominal temperature Tnom among the imax sheets of PEB test wafers.

After S141, the development control processor 310 ends the processing of the present flowchart and returns to the processing illustrated in FIG. 22.

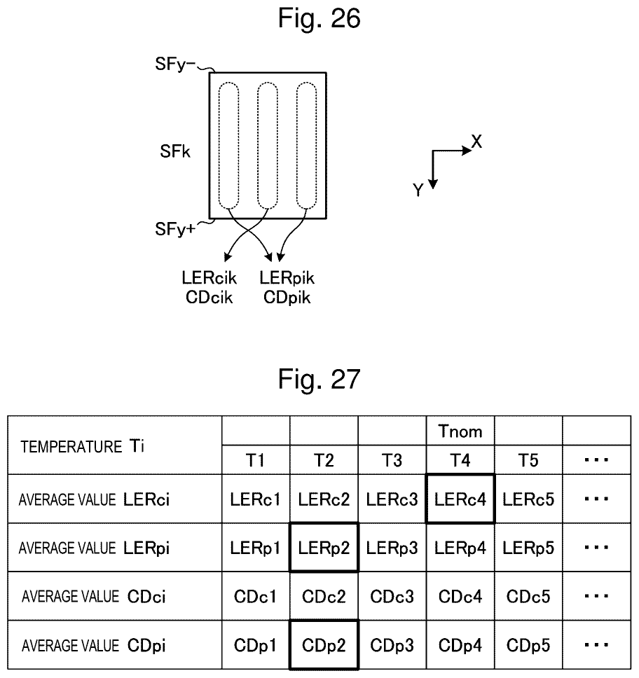

FIG. 26 conceptually illustrates regions where the line edge roughness LERcik and LERpik and the critical dimensions CDcik and CDpik are measured in the k-th scan field SFk. The line edge roughness LERcik and the critical dimension CDcik are obtained from the measurement result at the X axis direction center of the k-th scan field SFk, and the line edge roughness LERpik and the critical dimension CDpik are obtained from the measurement result at the X axis direction end of the k-th scan field SFk.

FIG. 27 illustrates a table summarizing the average values LERci, CDci, LERpi, and CDpi. The temperature Ti is set for each PEB test wafer WFi. It is assumed that the temperature Ti includes the nominal temperature Tnom. The average values LERci, CDci, LERpi and CDpi of the measurement results are calculated for each PEB test wafer WFi and for each position in the scan field.

FIG. 28 is a flowchart illustrating details of processing of setting a temperature distribution based on a measurement result. The processing illustrated in FIG. 28 corresponds to a subroutine of S15 in FIG. 22.

In S151, the development control processor 310 sets the counter i for counting the imax sheets of PEB test wafers to 1.

In S152, the development control processor 310 determines whether or not the average value LERpi of the line edge roughness LERpik at the X axis direction end of the i-th PEB test wafer WFi is within an allowable range. It is determined that the average value LERpi is within the allowable range when a difference between the average value LERpi and the reference LERc is equal to or smaller than a threshold.

In S153, the development control processor 310 determines whether or not the average value CDpi of the critical dimension CDpik at the X axis direction end of the i-th PEB test wafer WFi is within an allowable range.

When either of the average value LERpi and the average value CDpi is not within the allowable range (S152 or S153: NO), the development control processor 310 adds 1 to the value of the counter i in S154 and returns the processing to S152.

When each of the average value LERpi and the average value CDpi is within the corresponding allowable range (S152 and S153: YES), the development control processor 310 advances the processing to S155.

In S155, the development control processor 310 sets a temperature Tc at the X axis direction center of all the scan fields SF to the nominal temperature Tnom.

In S156, the development control processor 310 sets a temperature Tp at the X axis direction end of all the scan fields SF to the temperature Ti.

After S156, the development control processor 310 ends the processing of the present flowchart and returns to the processing illustrated in FIG. 22.

In an example illustrated in FIG. 27, when the nominal temperature Tnom is a temperature T4, the reference LERc is an average value LERc4. When a difference between the average value LERc4 and an average value LERp2 is equal to or smaller than a threshold and the average value CDp2 is within the allowable range, it is determined that each of the average value LERpi and the average value CDpi is within the corresponding allowable range, and the temperature Tp at the X axis direction end is set to a temperature T2.

FIG. 29 illustrates an example of a temperature distribution in the X axis direction set in the first embodiment. In FIG. 29, a horizontal axis represents a position in the X axis direction in the scan field SF, and a vertical axis represents the temperature. The temperature distribution in the X axis direction is set such that the temperature Tc is set at an X axis direction center c, the temperature Tp is set at an X axis direction end p, and a temperature gradient is gentle between the X axis direction center c and the X axis direction end p.

Depending on a temperature condition of the post-exposure baking, a diffusion length of acid to be a catalyst changes, and a velocity of chemical reaction with the acid as the catalyst also changes. By setting the temperature condition that each of the average value LERpi and the average value CDpi is within the corresponding allowable range, the line edge roughness can be adjusted and quality of the pattern formed on the photosensitive substrate can be improved.

While a case where the temperature Tc is higher than the temperature Tp is illustrated here, the temperature Tc may be lower than the temperature Tp as a result of setting the optimum temperature by the processing in FIG. 28.

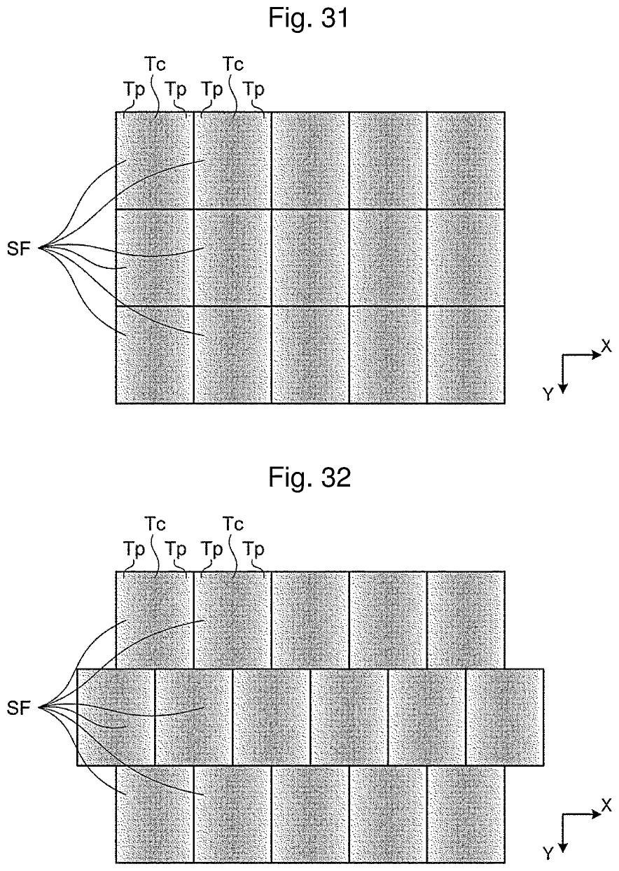

FIG. 30 illustrates an example of a temperature distribution in the Y axis direction set in the first embodiment. In FIG. 30, a horizontal axis represents a position in the Y axis direction in the scan field SF, and a vertical axis represents the temperature. The fixed temperature Tc is set regardless of the position in the Y axis direction at the X axis direction center c, and the fixed temperature Tp is set regardless of the position in the Y axis direction at the X axis direction end p. The temperature is fixed regardless of the position in the Y axis direction not only in a case where the temperature distribution in the Y axis direction of the photosensitive substrate is uniform but also in a case where a target temperature is uniform.

As illustrated in FIG. 29 and FIG. 30, in the temperature distribution in each of the scan fields SF, the temperature gradient in the Y axis direction is smaller than the temperature gradient in the X axis direction.

FIG. 31 illustrates a first example of a temperature distribution set in the first embodiment. In the first example, the scan fields SF are disposed in a rectangular grid shape. That is, at a corner of the scan field SF, boundary lines of the scan fields SF intersect in a cross shape. Rectangular grids include square grids. In each of the scan fields SF, the temperature Tc at the X axis direction center and the temperature Tp at the X axis direction end are set, and the temperature gradient is made gentle between the X axis direction center and the X axis direction end.

FIG. 32 illustrates a second example of a temperature distribution set in the first embodiment. In the second example, the scan fields SF are disposed to be shifted in the X axis direction for each column. In each of the scan fields SF, the temperature Tc at the X axis direction center and the temperature Tp at the X axis direction end are set, and the temperature gradient is made gentle between the X axis direction center and the X axis direction end. In the second example, the temperature gradient at a boundary with the scan field SF adjacent in the Y axis direction increases.

In each of FIG. 31 and FIG. 32, the temperature distributions in the scan fields SF are equal to each other.

When setting the temperature distribution in either one of FIG. 31 and FIG. 32, the development control processor 310 may separately acquire disposition data of the scan fields SF on the photosensitive substrate and set the temperature distribution so as to match the disposition data of the scan fields SF.

In addition, while a case is illustrated in which the temperature distribution in the X axis direction is symmetrical about a straight line parallel to the Y axis direction, the temperature distribution may not be symmetrical. For example, the temperature Tp may be separately set at an end in a +X direction and at an end in a −X direction.

### 2.2 Effect

(1) A photosensitive substrate developing method according to the first embodiment includes the following.

The photosensitive substrate exposed by scanning each of the scan fields SF included in the photosensitive substrate in the Y axis direction with the pulse laser beam including the center wavelengths via a photomask is heated so as to have the temperature distribution having the temperature gradient in the X axis direction intersecting the Y axis direction on the surface of the photosensitive substrate in each of the scan fields SF.

A developer is supplied to the surface of the photosensitive substrate to perform development after heating the photosensitive substrate.

Accordingly, even when the magnification chromatic aberration is generated when the exposure is performed using multiple wavelengths, by providing the temperature gradient in the X axis direction in the temperature distribution of the post-exposure baking, the line edge roughness can be adjusted and the quality of the pattern formed on the photosensitive substrate can be improved.

(2) In the first embodiment, the photosensitive substrate is heated so as to have the temperature distribution in which the temperature gradient in the Y axis direction is smaller than the temperature gradient in the X axis direction in each of the scan fields SF.

Since a shape of the beam cross section B of the pulse laser beam at the position of the workpiece table WT (see FIG. 1) is long in the X axis direction, the magnification chromatic aberration is larger in the X axis direction than in the Y axis direction. By increasing the temperature gradient in the X axis direction and performing the post-exposure baking with the temperature distribution corresponding to the position in the X axis direction, the line edge roughness can be appropriately adjusted.

(3) In the first embodiment, the photosensitive substrate is heated so as to have the temperature distribution uniform in the Y axis direction in each of the scan fields SF.

Since the magnification chromatic aberration in the Y axis direction is not large and the scanning is averaged by irradiating one part multiple times while performing the scanning in the Y axis direction even when there is the aberration, by performing post-exposure baking with the temperature distribution uniform in the Y axis direction, the line edge roughness can be appropriately adjusted.

(4) In the first embodiment, the photosensitive substrate is heated so as to have the temperature distribution symmetrical about the straight line parallel to the Y axis direction in each of the scan fields SF.

Since the magnification chromatic aberration can be generated symmetrically about the straight line parallel to the Y axis direction, by performing the post-exposure baking with the symmetrical temperature distribution, the line edge roughness can be appropriately adjusted.

(5) According to the first embodiment, the temperature distributions in the scan fields SF are equal to each other.

Accordingly, the line edge roughness can be appropriately adjusted when the exposure conditions of the scan fields SF are the same.

(6) In the first embodiment, the scan fields SF are disposed in the rectangular grid shape.

Accordingly, the temperature gradient at the boundary with the scan field SF adjacent in the Y axis direction is made gentle, and the post-exposure baking can be performed with an appropriate temperature distribution.

(7) In the first embodiment, the photosensitive substrate is heated by the hot plate set so as to have the temperature gradient in the X axis direction.

Accordingly, by setting the temperature gradient of the hot plate, the temperature distribution of the post-exposure baking can be appropriately controlled.

(8) The photosensitive substrate developing method according to the first embodiment further includes the following.

The PEB test wafer WFi exposed by scanning each of the scan fields SF included in the PEB test wafer WFi in the Y axis direction with the pulse laser beam including the center wavelengths via the PEB test mask is heated.

A developer is supplied to the surface of the PEB test wafer WFi to perform development after heating the PEB test wafer WFi.

The wafer pattern of the PEB test wafer WFi is measured after developing the PEB test wafer WFi.

The temperature distribution is set based on the measurement result of the wafer pattern of the PEB test wafer WFi.

Accordingly, by using the measurement result of the wafer pattern, the temperature distribution can be appropriately set.

(9) In the first embodiment, the PEB test wafers including the PEB test wafer WFi are heated at different temperatures T1.

Accordingly, by using a result of the post-exposure baking by the different temperatures T1, an appropriate temperature can be set.

(10) In the first embodiment, each of the PEB test wafers is heated so as to have the uniform temperature distribution.

Accordingly, since accurate temperature control can be performed in the post-exposure baking of the PEB test wafer WFi, data indicating a relation between the temperature of the post-exposure baking and the measurement result of the wafer pattern can be more accurate, and the temperature distribution can be appropriately set.

(11) In the first embodiment, the average values LERci, CDci, LERpi, and CDpi of the measurement results of the wafer pattern of the PEB test wafer WFi are calculated for each temperature T1 and for each position in the X axis direction in each of the scan fields SF, and the temperature distribution in the X axis direction is set based on the average values LERci, CDci, LERpi, and CDpi.

Accordingly, even when the measurement results slightly vary, by using the average values LERci, CDci, LERpi, or CDpi, accurate measurement data can be obtained.

(12) In the first embodiment, the temperature is specified at which the measurement result of the wafer pattern of the PEB test wafer WFi is within the allowable range at the position of the X axis direction end away from the X axis direction center in each of the scan fields SF, and the temperature distribution is set based on the specified temperature.

Accordingly, the appropriate temperature distribution can be set in accordance with the position in the X axis direction in the scan field SF.

(13) In the first embodiment, the measurement result of the wafer pattern of the PEB test wafer WFi includes the average value LERpi of the line edge roughness at the position of the X axis direction end, and the temperature distribution is specified such that the average value LERpi is within the allowable range.

Accordingly, since the temperature distribution of the post-exposure baking is set after actually measuring the line edge roughness, the line edge roughness can be accurately improved.

(14) In the first embodiment, when the difference between the reference LERc at the X axis direction center and the average value LERpi of the line edge roughness at the position of the X axis direction end in a case where the PEB test wafer WFi is heated at the nominal temperature Tnom and developed is equal to or smaller than the threshold, it is determined that the average value LERpi at the position of the X axis direction end is within the allowable range.

Accordingly, by determining the difference from the reference LERc, the line edge roughness at the X axis direction end can be made close to that at the X axis direction center.

(15) In the first embodiment, the measurement result of the wafer pattern of the PEB test wafer WFi further includes the average value CDpi of the critical dimension at the position of the X axis direction end, and the temperature distribution is specified such that each of the average value LERpi of the line edge roughness at the position of the X axis direction end and the average value CDpi of the critical dimension is within the corresponding allowable range.

Accordingly, both of the line edge roughness and the critical dimension can be improved.

In other respects, the first embodiment is similar to the comparative example.

### 3. Combination of Temperature Distribution of Post-Exposure Baking and OPC

### 3.1 Operation

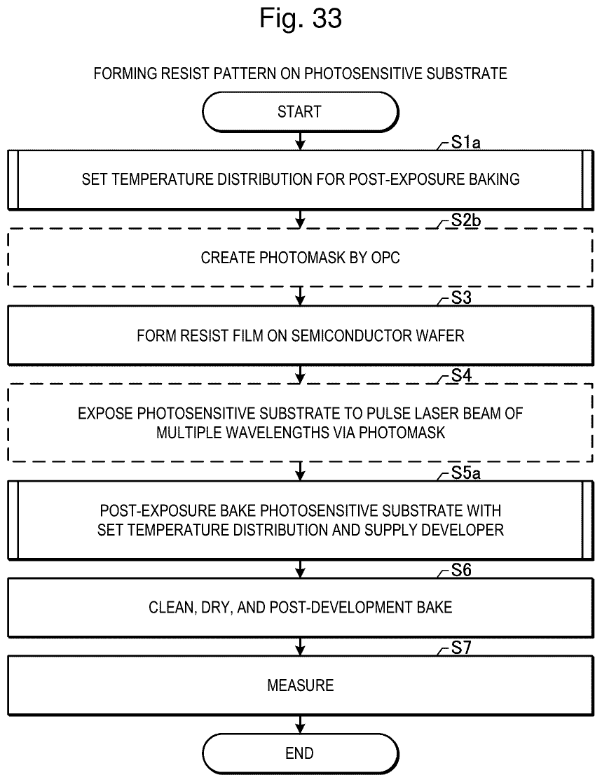

FIG. 33 is a flowchart illustrating processing of forming a resist pattern on a photosensitive substrate in a second embodiment. Although FIG. 33 mainly illustrates the processing of the developing device 300, FIG. 33 also includes the processing of the exposure apparatus 200 in part.

The processing of setting the temperature distribution in S1a is the same as the processing in the first embodiment described with reference to FIG. 20 and FIG. 22. However, the second embodiment is different from the first embodiment in the following points.
(a) While the critical dimensions CDcik and CDpik are measured as the wafer pattern and the average values CDci and CDpi thereof are calculated in S13 in FIG. 22 and in S134, S135, and S138 in FIG. 25 in the first embodiment, the critical dimensions CDcik and CDpik are not measured and the average values CDci and CDpi are not calculated either in the second embodiment.
(b) While whether or not the average value CDpi of the critical dimension is within the allowable range is determined in S15 in FIG. 22 and in S153 in FIG. 28 in the first embodiment, whether or not the average value CDpi of the critical dimension is within the allowable range is not determined in the second embodiment.

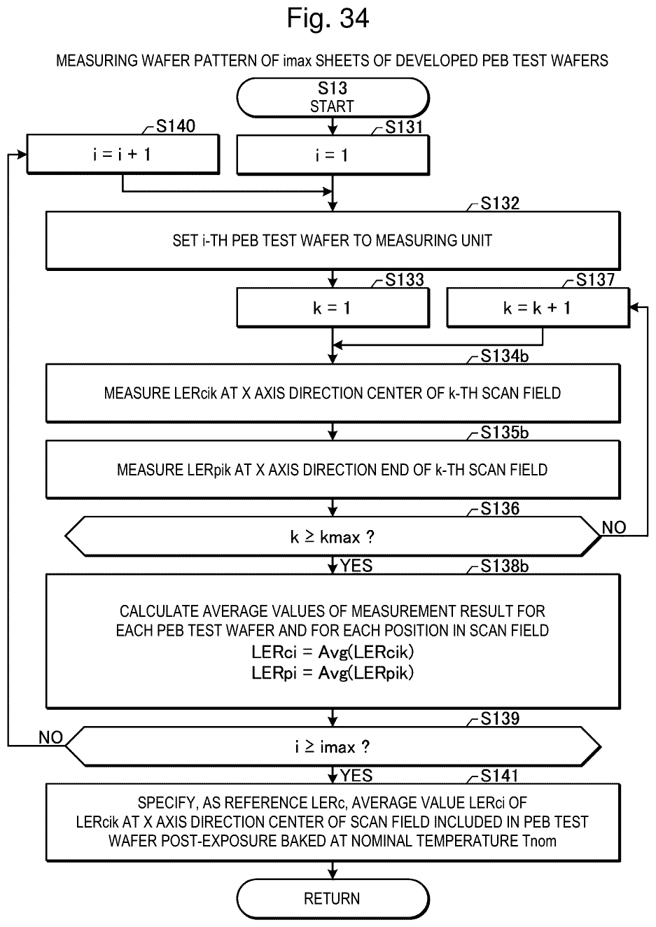

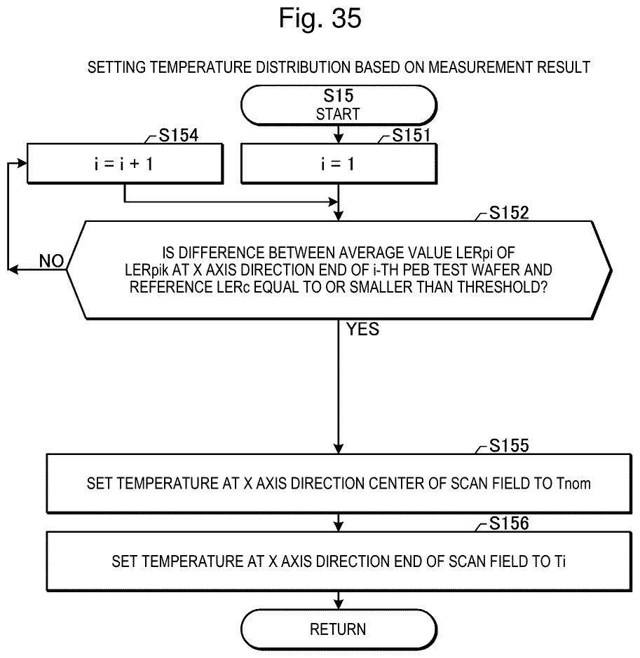

FIG. 34 and FIG. 35 illustrate details of processing of S13 and S15 in the second embodiment, respectively. FIG. 34 corresponds to FIG. 25 in the first embodiment, and FIG. 35 corresponds to FIG. 28 in the first embodiment.

As illustrated in FIG. 34, the development control processor 310 measures only the line edge roughness LERcik and LERpik in S134b and S135b, and calculates the average values LERci and LERpi in S138b.

As illustrated in FIG. 35, the development control processor 310 determines whether or not the average value LERpi of the line edge roughness is within the allowable range in S152.

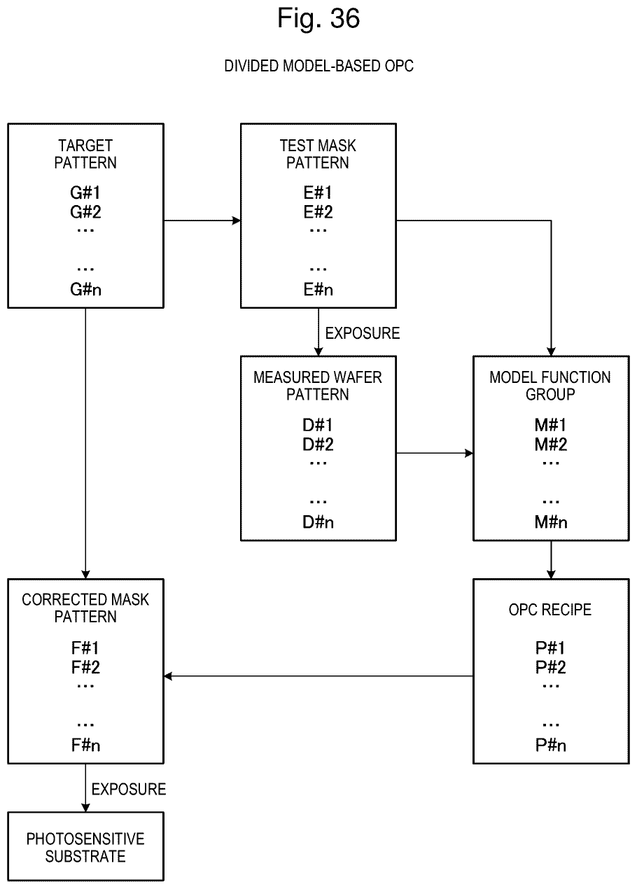

Referring back to FIG. 33, in S2b, a photomask is created by the OPC. The OPC allows the critical dimension to be within the allowable range. Details of S2b will be described later with reference to FIG. 36 to FIG. 41.

The processing from S3 to S7 is the same as that in the first embodiment.

FIG. 36 is a conceptual diagram of divided model-based OPC in the second embodiment. The divided model-based OPC differs from the model-based OPC in the comparative example in that each of the target pattern G, the test mask pattern E, the measured wafer pattern D, the model function group M, the OPC recipe P, and the corrected mask pattern F is created for each of a plurality of divided regions #1 to #n, and the model-based OPC is performed for each of the division regions #1 to #n.

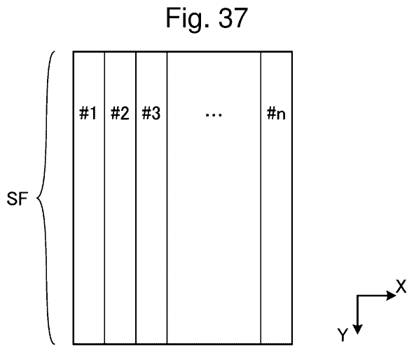

FIG. 37 illustrates the divided regions #1 to #n included in the scan field SF of the OPC test wafer. A variable n is an integer equal to or larger than 2, and the divided regions #1, #2, . . . , and #n are aligned in this order in the X axis direction on the surface of the OPC test wafer. The widths in the X axis direction of the divided regions #1 to #n are preferably equal to each other. The number of the divided regions #1 to #n, that is, the value of n is preferably 3 or larger and 15 or smaller.

Referring back to FIG. 36, the measured wafer pattern D obtained from the scan field SF of the OPC test wafer is divided into measured wafer patterns D #1 to D #n corresponding to the divided regions #1 to #n.

One scan field SF included in the OPC test wafer corresponds to a region where the test mask pattern E formed on one OPC test mask is transferred by scanning of one time, and is in a correspondence relation with the OPC test mask. The test mask pattern E is also divided into test mask patterns E #1 to E #n corresponding to the divided regions #1 to #n.

One scan field SF included in the OPC test wafer is in the correspondence relation with one scan field SF included in the photosensitive substrate. The target pattern G to be formed on the photosensitive substrate is also divided into target patterns G #1 to G #n corresponding to the divided regions #1 to #n.

One scan field SF included in the photosensitive substrate corresponds to a region where the corrected mask pattern F of one photomask is transferred by scanning of one time, and is in the correspondence relation with the photomask. The corrected mask pattern F is also divided into corrected mask patterns F #1 to F #n corresponding to the divided regions #1 to #n.

In the divided model-based OPC, model function groups M #1 to M #n corresponding to the divided regions #1 to #n are created, and OPC recipes P #1 to P #n corresponding to the divided regions #1 to #n are created.

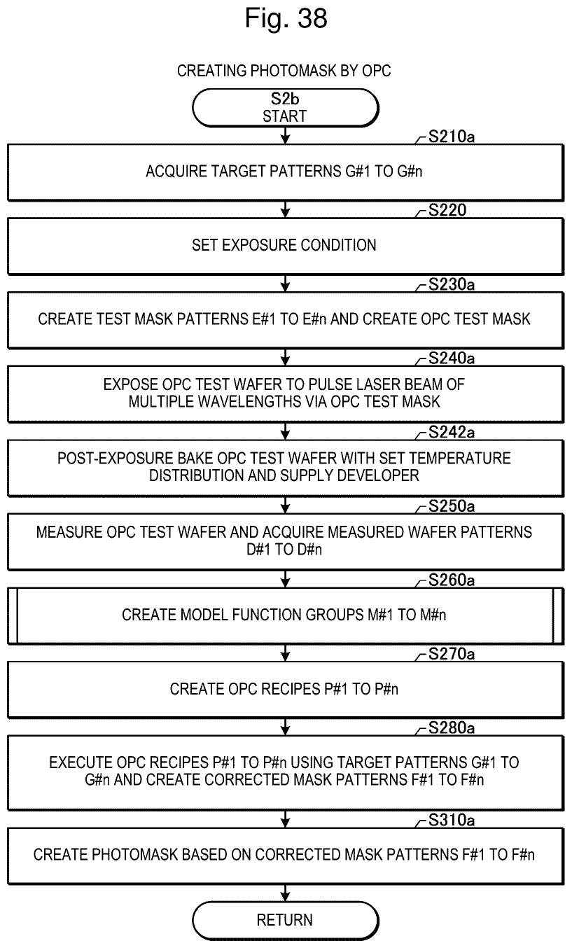

FIG. 38 is a flowchart of the divided model-based OPC. The processing illustrated in FIG. 38 is mainly performed by a processor such as the exposure control processor 210.

In S210a, the processor acquires the target patterns G #1 to G #n. For example, the target patterns G #1 to G #n are acquired by dividing the target pattern G designed by a semiconductor chip designer into the divided regions #1 to #n.

Processing of S220 is the same as the processing in the model-based OPC described with reference to FIG. 14.

In S230a, the processor creates the test mask patterns E #1 to E #n based on the target patterns G #1 to G #n. The different test mask patterns E #1 to E #n may be created depending on the divided regions #1 to #n like creating the test mask pattern E #1 based on the characteristic shape included in the target pattern G #1 and creating the test mask pattern E #2 based on the characteristic shape included in the target pattern G #2, for example. Alternatively, the test mask patterns E #1 to E #n including a common test mask pattern, that is, the same pattern shape may be created based on the characteristic shape included in the target patterns G #1 to G #n.

According to the test mask patterns E #1 to E #n, an OPC test mask is created by the mask manufacturing device.

In S240a, the exposure apparatus 200 exposes the OPC test wafer by scanning the OPC test wafer via the OPC test mask. The OPC test wafer is exposed by the light of multiple wavelengths used for the exposure of the photosensitive substrate.

In S242a, the processor controls the processing unit 302 to post-exposure bake the OPC test wafer with the temperature distribution set in S1a in FIG. 33 and to supply a developer to the surface of the OPC test wafer.

Further, the developed photosensitive substrate is cleaned, dried, and post-development baked, and when etching is to be performed, an unillustrated etching device performs etching to pattern the OPC test wafer.

In S250a, the processor measures the wafer pattern of the OPC test wafer, and acquires the measured wafer patterns D #1 to D #n indicating the measurement results in the divided regions #1 to #n.

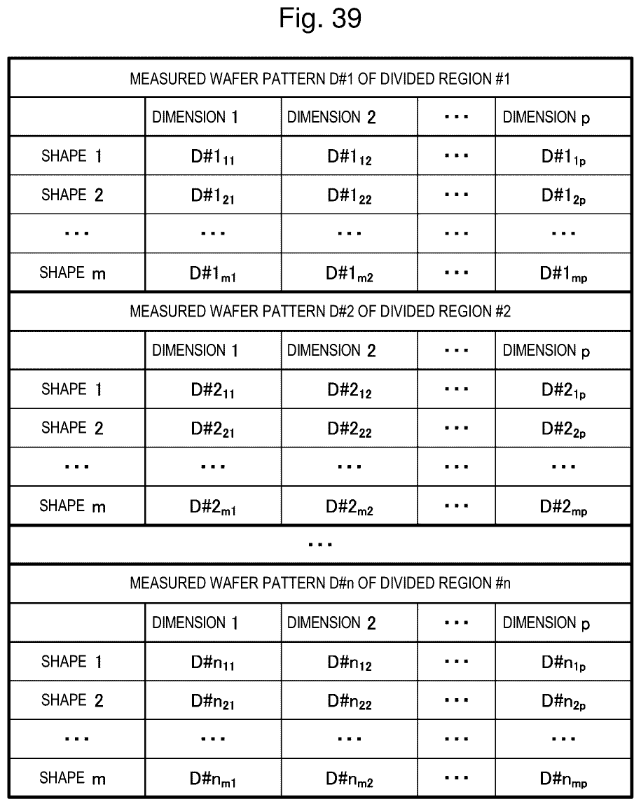

FIG. 39 illustrates a data structure of the measured wafer patterns D #1 to D #n. Each of the measured wafer patterns D #1 to D #n includes p pieces of dimensions measured for each of m pieces of shapes 1 to m.

When the test exposure is performed on the scan fields SF included in the OPC test wafer using one OPC test mask, average values for each divided region, for each shape, and for each dimension are calculated from the measurement results in the scan fields SF to attain the measured wafer patterns D #1 to D #n.

Referring back to FIG. 38, in S260a, the processor creates the model function groups M #1 to M #n based on the test mask patterns E #1 to E #n and the measured wafer patterns D #1 to D #n. For example, the model function group M #1 is created based on the test mask pattern E #1 and the measured wafer pattern D #1, and the model function group M #2 is created based on the test mask pattern E #2 and the measured wafer pattern D #2.

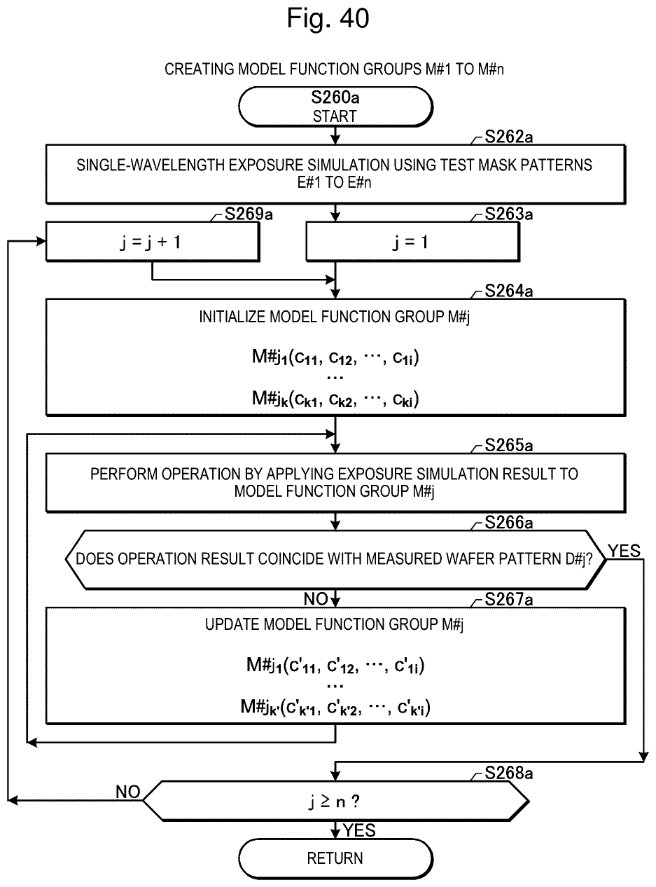

FIG. 40 is a flowchart illustrating details of processing of creating the model function groups M #1 to M #n. The processing illustrated in FIG. 40 corresponds to a subroutine of S260a in FIG. 38.

In S262a, the processor performs the exposure simulation using test mask patterns E #1 to E #n. The exposure simulation may be performed using light including a smaller number of center wavelengths than the pulse laser beam including the center wavelengths with which the OPC test wafer is scanned. The exposure simulation is preferably performed at a single wavelength.

In S263a, a value of a counter j is set to an initial value of 1. The counter j specifies one of the model function groups M #1 to M #n and also specifies one of the test mask patterns E #1 to E #n and one of the measured wafer patterns D #1 to D #n.

Processing of S264a to S267a is the same as the processing of S264 to S267 described with reference to FIG. 16. However, one of the model function groups M #1 to M #n specified by the counter j is created by using the exposure simulation result for which one of the test mask patterns E #1 to E #n specified by the counter j is used and one of the measured wafer patterns D #1 to D #n specified by the counter j. When determination in S266a is YES and one of the model function groups M #1 to M #n is created, the processor advances the processing to S268a.

In S268a, the processor determines whether or not the value of the counter j is equal to or larger than n. When the value of the counter j is smaller than n (S268a: NO), the processor adds 1 to the value of the counter j in S269a, returns the processing to S264a, and sets the model function group M #j of another divided region. When the value of the counter j is equal to or larger than n, the processor ends the processing of the present flowchart and returns to the processing illustrated in FIG. 38.

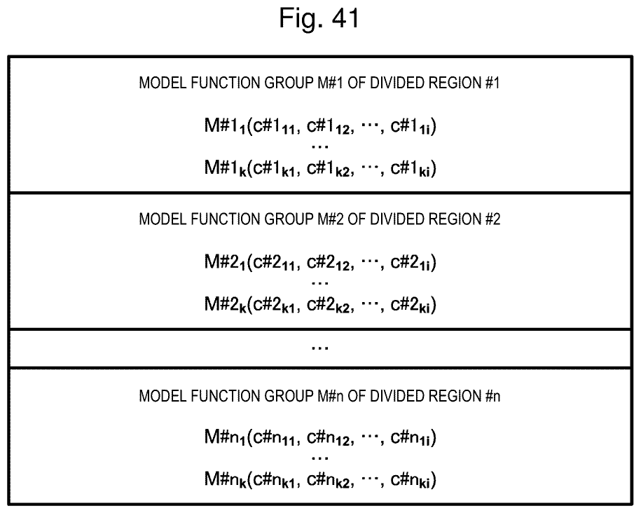

FIG. 41 illustrates an example of the model function groups M #1 to M #n. When one of the model function groups M #1 to M #n is specified by j, one model function group M #j includes k pieces of functions M #j₁ to M #jₖ. The number of the functions M #j1 to M #jk, that is, the value of k, may be different from each other in the model function groups M #1 to M #n.

Referring back to FIG. 38, in S270a, the processor creates the OPC recipes P #1 to P #n based on the model function groups M #1 to M #n, respectively.

In S280a, the processor executes the OPC recipes P #1 to P #n using the target patterns G #1 to G #n, respectively, and creates the corrected mask patterns F #1 to F #n. Thus, for example, the corrected mask pattern F #1 is created based on the target pattern G #1 and the model function group M #1, and the corrected mask pattern F #2 is created based on the target pattern G #2 and the model function group M #2.

In S310a, the mask manufacturing device creates a photomask based on the corrected mask patterns F #1 to F #n, and ends the processing of the present flowchart.

### 3.2 Effect

(16) A photomask creating method according to the second embodiment is a creating method of a photomask used in photolithography using a pulse laser beam including a plurality of center wavelengths, and includes the following.

A wafer pattern of an OPC test wafer that is exposed by scanning the OPC test wafer in the Y axis direction with a pulse laser beam via an OPC test mask and is developed by supplying a developer to a surface of the OPC test wafer heated so as to have a temperature distribution having a temperature gradient in the X axis direction intersecting the Y axis direction on the surface of the OPC test wafer in each of the scan fields SF included in the OPC test wafer is measured to acquire the measured wafer patterns D #1 to D #n indicating measurement results in the divided regions #1 to #n aligned in the X axis direction.

The corrected mask patterns F #1 to F #n for creating a photomask are created based on the test mask patterns E #1 to E #n formed on the OPC test mask, the measured wafer patterns D #1 to D #n, and the target patterns G #1 to G #n which are target wafer patterns of the photosensitive substrate.

The photomask is created based on the corrected mask patterns F #1 to F #n.

Accordingly, by using the measurement results in the divided regions #1 to #n, the OPC considering the off-axis chromatic aberration can be executed and the corrected mask patterns F #1 to F #n can be created.

In the first embodiment, although the temperature distribution of the post-exposure baking is set so that each of the line edge roughness and the critical dimension is within the corresponding allowable range, a solution in which each of the line edge roughness and the critical dimension is within the corresponding allowable range may not be obtained. According to the second embodiment, while the line edge roughness is adjusted according to the temperature distribution of the post-exposure baking, the critical dimension can be adjusted by the OPC of each of the divided regions #1 to #n.

(17) The photomask creating method according to the second embodiment further includes the following.

The PEB test wafer WFi exposed by scanning each of the scan fields SF included in the PEB test wafer WFi in the Y axis direction with the pulse laser beam including the center wavelengths via the PEB test mask is heated.

A developer is supplied to the surface of the PEB test wafer WFi to perform development after the PEB test wafer WFi is heated.

The wafer pattern of the PEB test wafer WFi is measured after developing the PEB test wafer WFi.

The temperature distribution is set based on the measurement result of the wafer pattern of the PEB test wafer WFi.

Accordingly, since the temperature distribution for post-exposure baking the OPC test wafer can be set based on the measurement result of the wafer pattern of the PEB test wafer WFi, the OPC test wafer can be accurately created.

(18) In the second embodiment, the temperature distribution is specified such that the average value LERpi of the line edge roughness at the position of the X axis direction end away from the X axis direction center in each of the scan fields SF is within the allowable range, and the corrected mask patterns F #1 to F #n are generated such that the critical dimension at the position of the X axis direction end is within the allowable range.

Accordingly, both of the line edge roughness and the critical dimension at the position of the X axis direction end can be improved.

(19) The photosensitive substrate developing method according to the second embodiment includes the following.

A photomask is created by the aforementioned creating method including the OPC considering the off-axis chromatic aberration.

The photosensitive substrate exposed by scanning the photosensitive substrate in the Y axis direction with the pulse laser beam including the center wavelengths via the photomask is heated so as to have the set temperature distribution.

A developer is supplied to the surface of the photosensitive substrate to perform development after the photosensitive substrate is heated.

Accordingly, the pattern on the photosensitive substrate can be formed with high accuracy.

While the second embodiment describes a case where the model-based OPC is executed for each of the divided regions #1 to #n, the present disclosure is not limited thereto, and the rule-based OPC may be executed for each of the divided regions #1 to #n, for example.

In other respects, the second embodiment is similar to the first embodiment.

### 4. Others

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. A photosensitive substrate developing method, comprising:
heating a photosensitive substrate exposed by scanning each of a plurality of scan fields included in the photosensitive substrate in a first direction with a pulse laser beam including a plurality of center wavelengths via a photomask so as to have a temperature distribution having a temperature gradient in a second direction intersecting the first direction on a surface of the photosensitive substrate in each of the scan fields; and
supplying a developer to the surface of the photosensitive substrate to perform development after heating the photosensitive substrate.

2. The developing method according to claim 1, wherein
the photosensitive substrate is heated so as to have the temperature distribution in which a temperature gradient in the first direction is smaller than a temperature gradient in the second direction in each of the scan fields.

3. The developing method according to claim 1, wherein
the photosensitive substrate is heated so as to have the temperature distribution that is uniform in the first direction in each of the scan fields.

4. The developing method according to claim 1, wherein
the photosensitive substrate is heated so as to have the temperature distribution symmetrical about a straight line parallel to the first direction in each of the scan fields.

5. The developing method according to claim 1, wherein
the temperature distributions in the scan fields are equal to each other.

6. The developing method according to claim 1, wherein
the scan fields are disposed in a rectangular grid shape.

7. The developing method according to claim 1, wherein
the photosensitive substrate is heated by a hot plate set so as to have a temperature gradient in the second direction.

8. The developing method according to claim 1, further comprising:
heating a first test wafer exposed by scanning each of a plurality of scan fields included in the first test wafer in the first direction with the pulse laser beam including the center wavelengths via a first test mask;
supplying a developer to a surface of the first test wafer to perform development after heating the first test wafer;
measuring a wafer pattern of the first test wafer after developing the first test wafer; and
setting the temperature distribution based on a measurement result of the wafer pattern of the first test wafer.

9. The developing method according to claim 8, wherein
a plurality of first test wafers including the first test wafer are heated at different temperatures, respectively.

10. The developing method according to claim 9, wherein
each of the first test wafers is heated so as to have a uniform temperature distribution.

11. The developing method according to claim 9, wherein
average values of measurement results of the wafer pattern of the first test wafer are calculated for each temperature and for each position in the second direction in each of the scan fields, and the temperature distribution in the second direction is set based on the average values.

12. The developing method according to claim 11, wherein
the temperature at which the measurement result of the wafer pattern of the first test wafer is within an allowable range at a first position away from a center in the second direction in each of the scan fields is specified, and the temperature distribution is set based on the specified temperature.

13. The developing method according to claim 12, wherein
the measurement result of the wafer pattern of the first test wafer includes line edge roughness at the first position, and the temperature distribution is set such that the line edge roughness at the first position is within an allowable range.

14. The developing method according to claim 13, wherein
when a difference between line edge roughness at the center in the second direction and the line edge roughness at the first position in a case where the first test wafer is heated at a reference temperature and developed is equal to or smaller than a threshold, the line edge roughness at the first position is determined to be within the allowable range.

15. The developing method according to claim 13, wherein
the measurement result of the wafer pattern of the first test wafer further includes a critical dimension at the first position, and the temperature distribution is set such that each of the line edge roughness and the critical dimension at the first position is within a corresponding allowable range.

16. A creating method of a photomask used in photolithography using a pulse laser beam including a plurality of center wavelengths, the creating method comprising:
measuring a wafer pattern of a second test wafer that is exposed by scanning the second test wafer in a first direction with a pulse laser beam via a second test mask and is developed by supplying a developer to a surface of the second test wafer heated so as to have a temperature distribution having a temperature gradient in a second direction intersecting the first direction on the surface of the second test wafer in each of a plurality of scan fields included in the second test wafer, to acquire a measured wafer pattern indicating measurement results in each of a plurality of divided regions aligned in the second direction;
creating a corrected mask pattern for creating the photomask based on a test mask pattern formed on the second test mask, the measured wafer pattern, and a target pattern which is a target wafer pattern of a photosensitive substrate; and
creating the photomask based on the corrected mask pattern.

17. The creating method according to claim 16, further comprising:
heating a first test wafer exposed by scanning each of a plurality of scan fields included in the first test wafer in the first direction with the pulse laser beam including the center wavelengths via a first test mask;
supplying a developer to a surface of the first test wafer to perform development after heating the first test wafer;
measuring a wafer pattern of the first test wafer after developing the first test wafer; and
setting the temperature distribution based on a measurement result of the wafer pattern of the first test wafer.

18. The creating method according to claim 16, wherein
the temperature distribution is set such that line edge roughness at a first position away from a center in the second direction in each of the scan fields is within an allowable range, and
the corrected mask pattern is created such that a critical dimension at the first position is within an allowable range.

19. A photosensitive substrate developing method, comprising:
creating the photomask by the creating method according to claim 16;
heating the photosensitive substrate exposed by scanning the photosensitive substrate in the first direction with a pulse laser beam including a plurality of center wavelengths via the photomask so as to have the temperature distribution; and
supplying a developer to a surface of the photosensitive substrate to perform development after heating the photosensitive substrate.

20. An electronic device manufacturing method, comprising:
generating a pulse laser beam including a plurality of center wavelengths with a laser apparatus;
outputting the pulse laser beam to an exposure apparatus;
performing exposure by scanning each of a plurality of scan fields included in a photosensitive substrate in a first direction with the pulse laser beam via a photomask in the exposure apparatus;
heating the exposed photosensitive substrate so as to have a temperature distribution having a temperature gradient in a second direction intersecting the first direction on a surface of the photosensitive substrate in each of the scan fields; and
supplying a developer to the surface of the photosensitive substrate to perform development after heating the photosensitive substrate.
